(19) United States
(12) Patent Application Publication
(10) Pub. No.: US 2026/0140066 A1
(43) Pub. Date: May 21, 2026

(54) WAFER INSPECTION APPARATUS

(71) Applicant: Samsung Electronics Co., Ltd., Suwon-si (KR)

(72) Inventors: Karam Lee, Suwon-si (KR); Minsu Jo, Suwon-si (KR); Inyoung Choi, Suwon-si (KR); Kwangsoo Kim, Suwon-si (KR); Sangbin Park, Seoul (KR); Sangkyu Lim, Seoul (KR); Byeongkyu Cha, Suwon-si (KR)

(73) Assignees: Samsung Electronics Co., Ltd., Suwon-si, Gyeonggi-do (KR); MUTECH KOREA Co., Ltd., Geumcheong-gu, Seoul (KR)

(21) Appl. No.: 19/313,241

(22) Filed: Aug. 28, 2025

(30) Foreign Application Priority Data
Nov. 21, 2024 (KR) 10-2024-0167760

(51) Int. Cl. G01N 21/95; G01N 21/88; G06T 7/00; G06T 7/13

(52) U.S. Cl. CPC G01N 21/9503; G01N 21/8806; G01N 21/8851; G06T 7/001; G06T 7/13; G01N 2201/062; G01N 2201/103; G06T 2207/30148

(57) ABSTRACT

A wafer inspection apparatus includes a chuck having a wafer placed on a top surface thereof, an upper optical system acquiring an upper image of the wafer, and a bevel optical system located at a position rotated 90 degrees from the upper optical system in a circumferential direction and configured to acquire a bevel image of the wafer. The upper optical system includes an upper coaxial light source, an upper non-coaxial light source, and an upper detector. The bevel optical system includes a bevel light source including a plurality of bevel light-emitting diodes (LEDs) surrounding an outer surface of the bevel and a bevel detector.

### CROSS-REFERENCE TO RELATED APPLICATION(S)

This application is based on and claims priority under 35 U.S.C. § 119 to Korean Patent Application No. 10-2024-0167760, filed on Nov. 21, 2024, in the Korean Intellectual Property Office, the disclosure of which is incorporated by reference herein in its entirety.

### BACKGROUND

The probability of wafer breakage can increase due to small defects in the edge and/or bevel region of a wafer. Accordingly, it may be desired to precisely inspect the edge of a wafer throughout the semiconductor manufacturing processes, and the need of an apparatus capable of acquiring a high-resolution image of the edge of the wafer is increasing.

### SUMMARY

The present disclosure provides a wafer inspection apparatus capable of acquiring a high-resolution image of the edge of a wafer and having an increased image coverage.

The present disclosure is not limited to those mentioned above, and the present disclosure that has not been mentioned will be clearly understood by one of skill in the art from the description below.

According to an aspect of the present disclosure, a wafer inspection apparatus includes a chuck having a wafer placed on a top surface thereof, an upper optical system above the chuck and configured to acquire an upper image of an upper edge of the wafer, and a bevel optical system located at a position rotated 90 degrees from the upper optical system in a circumferential direction based on a central axis of the chuck and configured to acquire a bevel image of the wafer, wherein the upper optical system includes an upper coaxial light source above the wafer and configured to output first upper light radiated to the upper edge of the wafer in a vertical direction, an upper non-coaxial light source outside the wafer and configured to output second upper light radiated to the upper edge of the wafer at inclination with respect to the vertical direction, and an upper detector configured to detect the first upper light reflected from the upper edge of the wafer and the second upper light reflected from the upper edge of the wafer, and the bevel optical system includes a bevel light source arranged apart outward from a bevel of the wafer, the bevel light source including a plurality of bevel light-emitting diodes (LEDs) surrounding an outer surface of the bevel of the wafer and outputting bevel light radiated to a bevel apex of the wafer, and a bevel detector configured to detect the bevel light reflected from the bevel apex of the wafer.

According to another aspect of the present disclosure, a wafer inspection apparatus includes a chuck having a wafer placed on a top surface thereof, a lower optical system below the chuck and configured to acquire a lower image of a lower edge of the wafer, and a bevel optical system located at a position rotated 90 degrees from the lower optical system in a circumferential direction based on a central axis of the chuck and configured to acquire a bevel image of the wafer, wherein the lower optical system includes a lower coaxial light source below the wafer and configured to output first lower light radiated to the lower edge of the wafer in a vertical direction, a lower non-coaxial light source outside the wafer and configured to output second lower light radiated to the lower edge of the wafer at inclination with respect to the vertical direction, and a lower detector configured to detect the first lower light reflected from the lower edge of the wafer and the second lower light reflected from the lower edge of the wafer, and the bevel optical system includes a bevel light source arranged apart outward from a bevel of the wafer, the bevel light source including a plurality of bevel LEDs surrounding an outer surface of the bevel of the wafer and outputting bevel light radiated to a bevel apex of the wafer, and a bevel detector configured to detect the bevel light reflected from the bevel apex of the wafer.

According to a further aspect of the present disclosure, a wafer inspection apparatus includes a chuck having a wafer placed on a top surface thereof, an upper optical system above the chuck and configured to acquire an upper image of an upper edge of the wafer, a lower optical system arranged at a position symmetrical with the upper optical system with respect to a central axis of the chuck and configured to acquire a lower image of a lower edge of the wafer, a bevel optical system located at a position rotated 90 degrees from the upper optical system in a circumferential direction based on the central axis of the chuck and configured to acquire a bevel image of the wafer, and an alignment optical system arranged at a position symmetrical with the bevel optical system with respect to the central axis of the chuck and configured to acquire an alignment image used to inspect whether the wafer is aligned with the chuck, wherein the upper optical system includes an upper coaxial light source above the wafer and configured to output first upper light radiated to the upper edge of the wafer in a vertical direction, an upper non-coaxial light source outside the wafer and configured to output second upper light radiated to the upper edge of the wafer while at a first angle inclined with respect to the vertical direction, and an upper detector configured to detect the first upper light reflected from the upper edge of the wafer and the second upper light reflected from the upper edge of the wafer, the lower optical system includes a lower coaxial light source below the wafer and configured to output first lower light radiated to the lower edge of the wafer in the vertical direction, a lower non-coaxial light source outside the wafer and configured to output second lower light radiated to the lower edge of the wafer at a second angle inclined with respect to the vertical direction, and a lower detector configured to detect the first lower light reflected from the lower edge of the wafer and the second lower light reflected from the lower edge of the wafer, and the bevel optical system includes a bevel light source arranged apart outward from a bevel of the wafer, the bevel light source including a plurality of bevel LEDs surrounding an outer surface of the bevel of the wafer and outputting bevel light radiated to a bevel apex of the wafer, and a bevel detector configured to detect the bevel light reflected from the bevel apex of the wafer, wherein each of the first angle and the second angle is about 30 degrees to about 130 degrees.

### BRIEF DESCRIPTION OF THE DRAWINGS

Implementations will be more clearly understood from the following detailed description taken in conjunction with the accompanying drawings in which:

FIG. 1 is a schematic cross-sectional view of an equipment front-end module (EFEM) according to an implementation;

FIG. 2 is a block diagram illustrating a wafer inspection apparatus according to an implementation;

FIG. 3 is a cross-sectional view illustrating an edge of a wafer, according to an implementation;

FIG. 4 is a cross-sectional view illustrating the configuration of an upper optical system, according to an implementation;

FIG. 5 is a cross-sectional view illustrating first upper light and second upper light, according to an implementation;

FIG. 6 is a cross-sectional view illustrating the configuration of an upper optical system, according to an implementation;

FIG. 7 is a cross-sectional view illustrating the configuration of an upper optical system, according to an implementation;

FIG. 8 is a cross-sectional view illustrating the configuration of a lower optical system, according to an implementation;

FIG. 9 is a cross-sectional view illustrating first lower light and second lower light, according to an implementation;

FIG. 10 is a cross-sectional view illustrating the configuration of a bevel optical system, according to an implementation;

FIGS. 11A and 11B show upper images acquired by an upper optical system, according to an implementation;

FIGS. 12A and 12B show lower images acquired by a lower optical system, according to an implementation;

FIGS. 13A and 13B show bevel images acquired by a bevel optical system, according to an implementation;

FIG. 14 is a flowchart of a method of compensating, by a wafer inspection apparatus, for a wafer alignment error, according to an implementation;

FIGS. 15 and 16 are respectively an image and a graph illustrating an eccentricity identification method of a wafer inspection apparatus, according to an implementation;

FIG. 17 is a diagram illustrating a method of identifying, by a wafer inspection apparatus, an expected rotation trajectory, according to an implementation;

FIG. 18 is a flowchart of a method of identifying, by a wafer inspection apparatus, a boundary line of a wafer, according to an implementation; and

FIG. 19 is an image illustrating a method of acquiring, by a wafer inspection apparatus, an edge scan image, according to an implementation.

### DETAILED DESCRIPTION

Hereinafter, implementations are described in detail with reference to the accompanying drawings. In the drawing, like reference characters denote like elements, and redundant descriptions thereof will be omitted.

Here, a horizontal direction may include a first horizontal direction (a Y direction) and a second horizontal direction (an X direction), which cross each other. A direction crossing the first horizontal direction (the Y direction) and the second horizontal direction (the X direction) may be referred to as a vertical direction (a Z direction). A vertical level may refer to a height level of an element in the vertical direction (the Z direction).

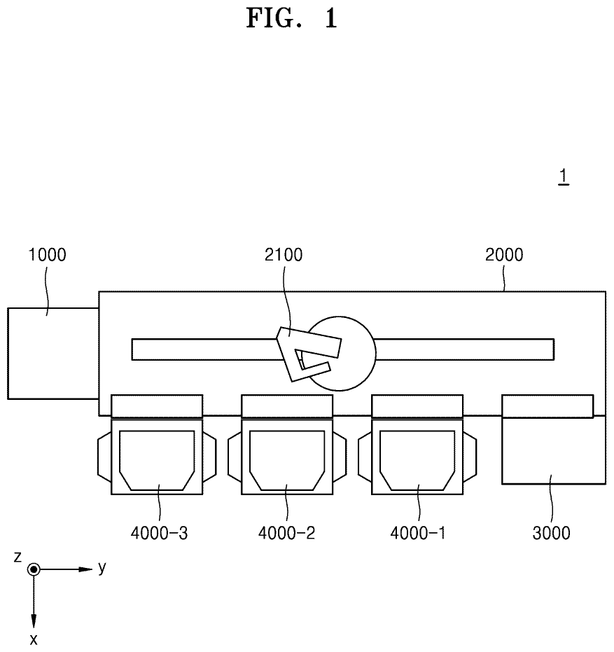

FIG. 1 is a schematic cross-sectional view of an equipment front-end module (EFEM) 1 according to an implementation.

Referring to FIG. 1, the EFEM 1 may include a wafer inspection apparatus 1000, a frame 2000, a transfer robot 2100, measuring equipment 3000, and first to third rod ports 4000-1, 4000-2, and 4000-3.

The transfer robot 2100 may be provided in the frame 2000. As shown in FIG. 1, the measuring equipment 3000 and the first to third rod ports 4000-1, 4000-2, and 4000-3 may be placed on a sidewall of the frame 2000. As shown in FIG. 1, the wafer inspection apparatus 1000 may be placed on another sidewall of the frame 2000.

Although not shown in FIG. 1, semiconductor process equipment may be placed on a sidewall of the frame 2000. The sidewall of the frame 200, on which the semiconductor process equipment is placed, may face the sidewall of the frame 2000, on which the measuring equipment 3000 and the first to third rod ports 4000-1, 4000-2, and 4000-3 are placed. For example, the semiconductor process equipment placed on the sidewall of the frame 2000 may include at least one of pieces of equipment, such as chemical-mechanical polishing (CMP) equipment, vapor-deposition equipment, and etching equipment, which are used in various types of semiconductor manufacturing processes.

The transfer robot 2100 may transfer a wafer. For example, the transfer robot 2100 may transfer a wafer from one the first to third rod ports 4000-1, 4000-2, and 4000-3 to the wafer inspection apparatus 1000. For example, the transfer robot 2100 may transfer a wafer from semiconductor process equipment on a sidewall of the frame 2000 to the wafer inspection apparatus 1000.

The measuring equipment 3000 may include various types of optical devices for measuring semiconductors. For example, the measuring equipment 3000 may include at least one selected from the group consisting of X-ray inspection equipment, optical microscope equipment, and scanning electron microscope equipment.

Each of the first to third rod ports 4000-1, 4000-2, and 4000-3 may include a front opening unified pod (FOUP) load port. Each of the first to third rod ports 4000-1, 4000-2, and 4000-3 may be configured to receive a wafer from the outside or output a wafer to the outside.

The wafer inspection apparatus 1000 may acquire an image of the edge of a wafer and may be placed on a sidewall of the frame 2000. In various semiconductor manufacturing processes, the wafer inspection apparatus 1000 may receive a wafer from the transfer robot 2100 and inspect the edge of the wafer.

According to an implementation, when CMP equipment is placed on a sidewall of the frame 2000, the transfer robot 2100 may transfer a wafer to the wafer inspection apparatus 1000 before a CMP process. The wafer inspection apparatus 1000 may inspect the state of the edge of the wafer before the CMP process to identify whether there is a defect in the edge of the wafer.

According to some implementations, the transfer robot 2100 may transfer a wafer to the wafer inspection apparatus 1000 before and after a CMP process. In this case, the wafer inspection apparatus 1000 may inspect the state of the edge of the wafer before and after the CMP process to identify whether there is a defect in the edge of the wafer after the CMP process.

As described above, the wafer inspection apparatus 1000 may include a structure placeable on a sidewall of the EFEM 1 and thus inspect the edge of a wafer in various semiconductor manufacturing processes.

Hereinafter, the configuration and effects of the wafer inspection apparatus 1000 are described in detail with reference to the accompanying drawings.

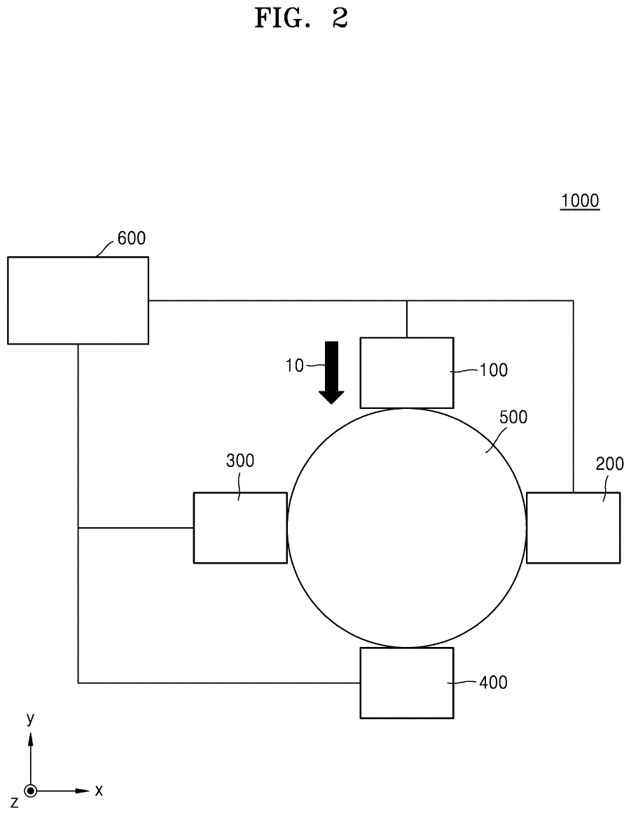

FIG. 2 is a block diagram illustrating the wafer inspection apparatus 1000 according to an implementation.

Referring to FIG. 2, the wafer inspection apparatus 1000 may include an alignment optical system 100, an upper optical system 200, a lower optical system 300, a bevel optical system 400, a chuck 500, and a controller 600.

In the descriptions below, the terms “alignment,” “upper,” “lower,” and “bevel” may be used as adjectives before nouns, such as “detector,” “light,” “image,” and the like, and may modify the nouns. For example, the terms “alignment,” “upper,” “lower,” and “bevel” before detector,” “light,” and “image” may respectively indicate which optical system the “detector” is included in, which optical system the “light” is used in, and which optical system the “image” is acquired by.

In detail, an “alignment detector” may indicate a detector included in the alignment optical system 100, and an “alignment image” may indicate an image acquired by the alignment optical system 100. For example, an “upper detector” may indicate a detector included in the upper optical system 200, and an “upper light source” may indicate a light source included in the upper optical system 200.

The alignment optical system 100 may refer to an optical system that acquires an alignment image to inspect the alignment of a wafer with the chuck 500. The alignment optical system 100 may include an alignment detector detecting an alignment image, an alignment light source emitting alignment light to a wafer, and an alignment mirror and lens that transmit the alignment light reflected from the wafer to the alignment detector.

As shown in FIG. 2, the alignment optical system 100 may be apart from the center of the chuck 500 in the first horizontal direction (e.g., a +Y direction). A wafer feeding direction 10 in which a wafer is fed to the chuck 500 may coincide with a direction from the alignment optical system 100 to the center of the chuck 500. The alignment optical system 100 may be arranged in a position symmetrical with the bevel optical system 400 with respect to the center of the chuck 500. However, this is just an example of the position of the alignment optical system 100, and the alignment optical system 100 may be arranged in various positions.

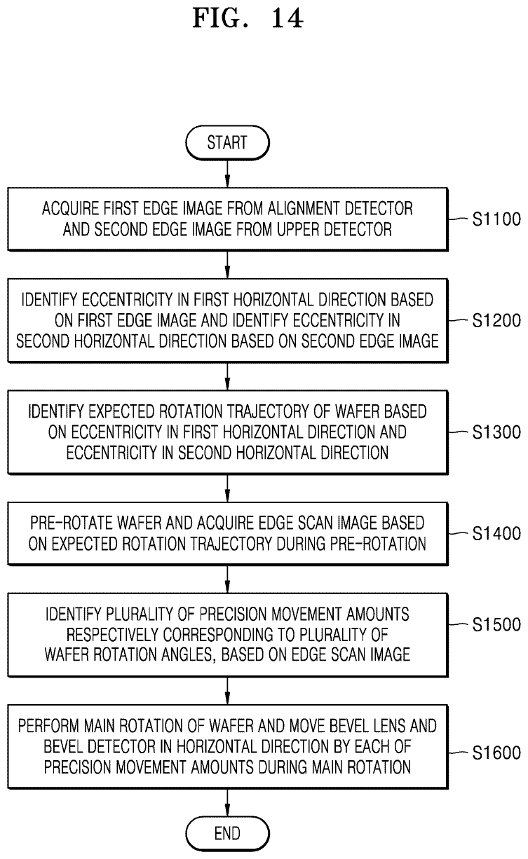

An alignment detector of the alignment optical system 100 may acquire an alignment image to inspect whether a wafer is aligned with the chuck 500. For example, the alignment detector may acquire an alignment image of an edge portion of a wafer, which is apart from the center of the chuck 500 in the first horizontal direction (e.g., the +Y direction), in the edge of the wafer arranged on the top surface of the chuck 500. The alignment detector may include a line scan camera or an area scan camera. The alignment image may include an edge region of the wafer and a dark region. The controller 600 may identify the boundary between the edge region and the dark region and identify whether the wafer is aligned with the chuck 500 in the first horizontal direction. An operation in which the controller 600 identifies alignment of a wafer is described in detail with reference to FIGS. 14 to 19 below.

The upper optical system 200 may refer to an optical system that acquires an upper image of an upper edge of a wafer. The upper optical system 200 may include an upper detector detecting an upper image, an upper light source emitting upper light to the upper edge, and an upper mirror, an upper lens, and an upper beam splitter, which are arranged on the light path of the upper light.

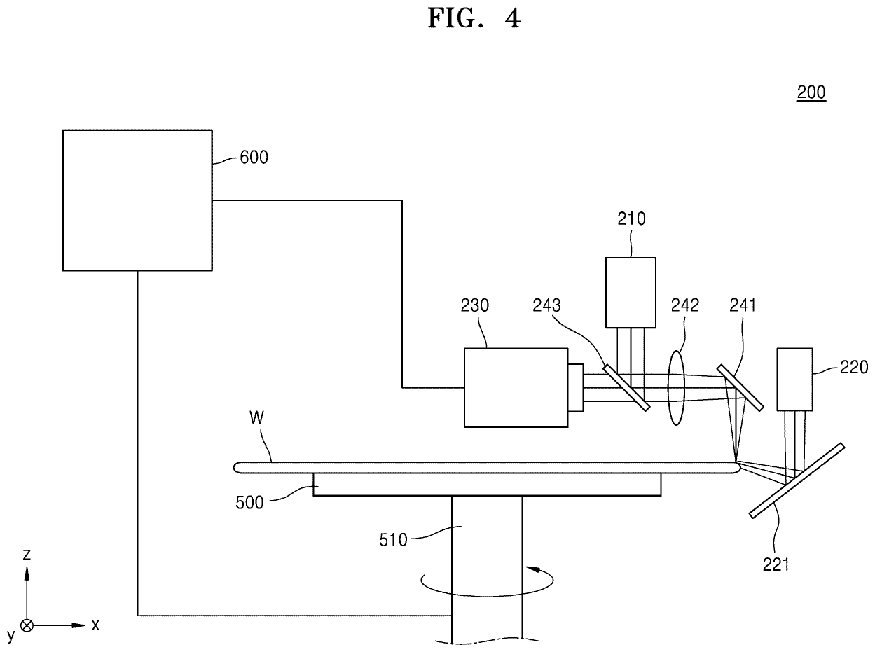

As shown in FIG. 2, the upper optical system 200 may be apart from the center of the chuck 500 in the second horizontal direction (e.g., a +X direction). The upper optical system 200 may be arranged in a position symmetrical with the lower optical system 300 with respect to the center of the chuck 500. However, this is just an example of the position of the upper optical system 200, and the upper optical system 200 may be arranged in various positions. Components included in the upper optical system 200 are described in detail with reference to FIGS. 4 to 7 below.

The lower optical system 300 may refer to an optical system that acquires a lower image of a lower edge of a wafer. The lower optical system 300 may include a lower detector detecting a lower image, a lower light source emitting lower light to the lower edge, and a lower mirror, a lower lens, and a lower beam splitter, which are arranged on the light path of the lower light.

As shown in FIG. 2, the lower optical system 300 may be apart from the center of the chuck 500 in the second horizontal direction (e.g., a −X direction) and may be arranged in a position opposite to the upper optical system 200. The lower optical system 300 may be arranged in a position symmetrical with the upper optical system 200 with respect to the center of the chuck 500.

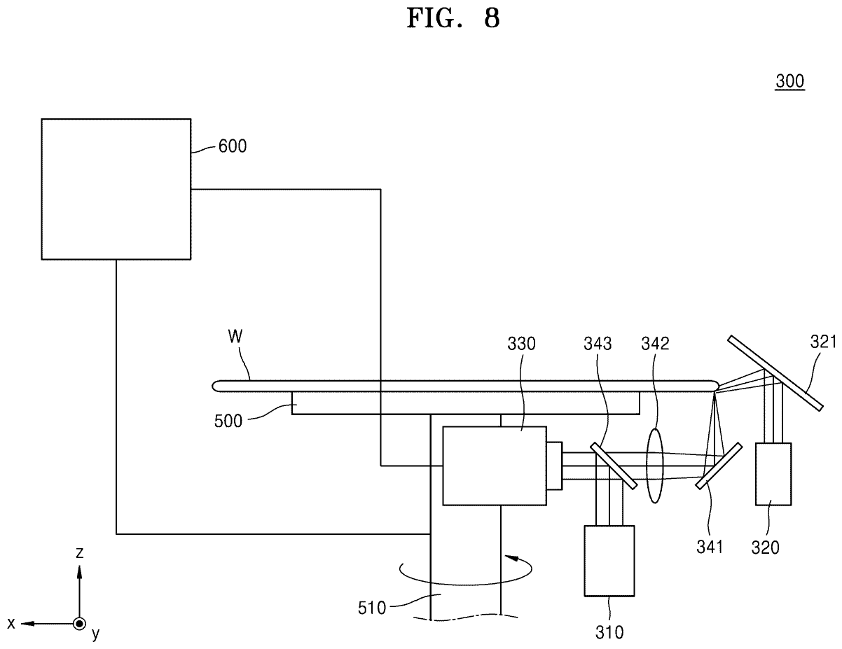

In detail, components of the lower optical system 300 and components of the upper optical system 200 may be arranged in a symmetrical structure with respect to the center of the chuck 500. For example, the lower detector of the lower optical system 300 and the upper detector of the upper optical system 200 may be arranged in a symmetrical structure with respect to the center of the chuck 500, and the lower light source of the lower optical system 300 and the upper light source of the upper optical system 200 may be arranged in a symmetrical structure with respect to the center of the chuck 500. Components of the lower optical system 300 are described in detail with reference to FIG. 8 below.

The bevel optical system 400 may refer to an optical system that acquires a bevel image of a bevel apex of a wafer. The bevel optical system 400 may include a bevel detector detecting a bevel image, a bevel light source emitting bevel light to a bevel apex, and a bevel mirror and lens, which are arranged on the light path of the bevel light.

As shown in FIG. 2, the bevel optical system 400 may be apart from the center of the chuck 500 in the first horizontal direction (e.g., a −Y direction) and may be arranged in a position opposite to the alignment optical system 100. In detail, the bevel optical system 400 may be arranged in a position symmetrical with the alignment optical system 100 with respect to the center of the chuck 500.

Although it is illustrated in FIG. 2 that the alignment optical system 100 is arranged at 12 o'clock of the center of the chuck 500, the upper optical system 200 is arranged in a position rotated 90 degrees clockwise from the alignment optical system 100, the bevel optical system 400 is arranged in a position rotated 90 degrees clockwise from the upper optical system 200, and the lower optical system 300 is arranged in a position rotated 90 degrees clockwise from the bevel optical system 400, this is just one of examples of arranging a plurality optical systems. The alignment optical system 100, the upper optical system 200, the lower optical system 300, and the bevel optical system 400 may be arranged in various manners.

In detail, with respect to the center of the chuck 500, the alignment optical system 100 and the bevel optical system 400 may face each other, the upper optical system 200 and the lower optical system 300 may face each other, and the separation angle between two adjacent optical systems may also be maintained as 90 degrees. Here, the separation angle may refer to an angle between straight lines from the center of the chuck 50 to multiple optical systems.

According to an implementation, on the basis of the center of the chuck 500, the bevel optical system 400 may be at 12 o'clock, the lower optical system 300 may be at 3 o'clock, the alignment optical system 100 may be at 6 o'clock, and the upper optical system 200 may be at 9 o'clock.

According to some implementations, on the basis of the center of the chuck 500, the upper optical system 200 may be at 12 o'clock, the bevel optical system 400 may be at 3 o'clock, the lower optical system 300 may be at 6 o'clock, and the alignment optical system 100 may be at 9 o'clock.

A wafer may be placed on the top surface of the chuck 500, and the chuck 500 may fix the wafer on the top surface thereof. For example, the chuck 500 may fix the wafer on the top surface thereof based on an electrostatic force. The chuck 500 may include an electrode therein to chuck or dechuck a wafer. Alternatively, the chuck 500 may fix a wafer based on vacuum-adsorption.

The chuck 500 may be connected to a rotating stage. The rotating stage may provide torque to the chuck 500. The chuck 500 may perform a rotational motion based on the torque. In the rotational motion, the chuck 500 may rotate in a circumferential direction (e.g., a clockwise direction, or a counterclockwise direction) with the vertical direction (the Z direction) as a rotation axis. As the chuck 500 performs the rotational motion, a wafer on the top surface of the chuck 500 may perform a rotational motion at the same angular velocity as the chuck 500.

The upper optical system 200, the lower optical system 300, and the bevel optical system 400 may continuously acquire images of the edge of a wafer that performs a rotational motion at a certain angular velocity. For example, the upper optical system 200 may continuously acquire upper images of the upper edge of a wafer. Specifically, the upper optical system 200 may continuously acquire upper images corresponding to a wafer rotation angle of 0 degrees, 1 degree, . . . , and 360 degrees, respectively. Based on the same principle, each of the lower optical system 300 and the bevel optical system 400 may respectively acquire a lower image and a bevel image in correspondence to each of multiple wafer rotation angles.

The controller 600 may be operatively connected to each of the alignment optical system 100, the upper optical system 200, the lower optical system 300, the components of the bevel optical system, the chuck 500, etc. The controller 600 may include at least one selected from the group consisting of a microprocessor, a digital signal processor, and similar processing devices.

For example, the controller 600 may acquire an image from a detector of each of a plurality of optical systems and may control a rotating stage to allow a wafer to perform a rotational motion at a constant angular velocity. The control operation of the controller 600 is described in detail below.

According to an implementation, the wafer inspection apparatus 1000 may include the components described above and thus acquire an image of the edge of a wafer on the top surface of the chuck 500. In particular, the wafer inspection apparatus 1000 may include the upper optical system 200 acquiring an upper image of an upper edge of a wafer, the lower optical system 300 acquiring a lower image of a lower edge of the wafer, and the bevel optical system 400 acquiring a bevel image of a bevel apex of the wafer, thereby acquiring a high-resolution image of the edge of wafer. As described above, a plurality of optical systems of the wafer inspection apparatus 1000 may be efficiently arranged in a single space, and accordingly, the wafer inspection apparatus 1000 may inspect the edge of a wafer at a high speed.

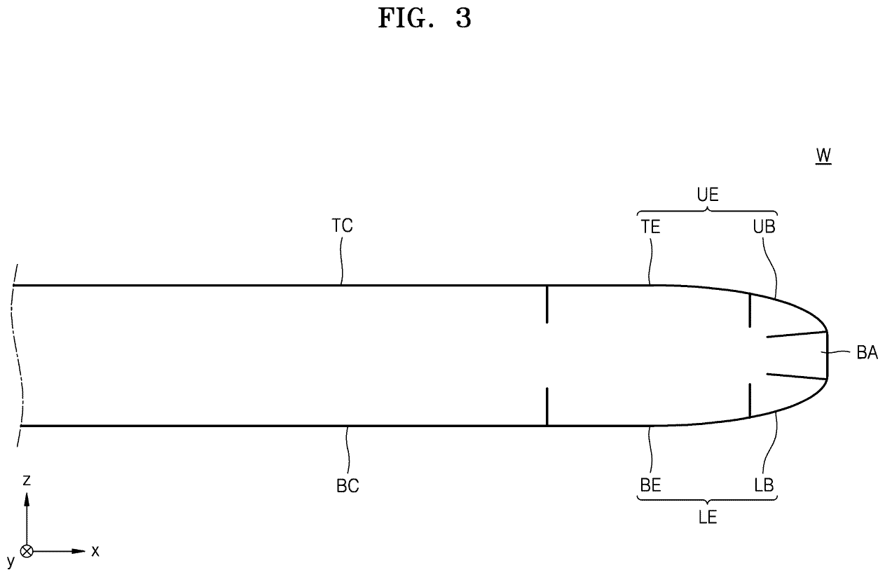

The edge of a wafer is described in detail with reference to FIG. 3 below.

FIG. 3 is a cross-sectional view illustrating an edge of a wafer W, according to an implementation.

Referring to FIG. 3, the wafer W may include a top center TC, a top edge TE, an upper bevel UB, a bevel apex BA, a lower bevel LB, a bottom edge BE, and a bottom center BC. In the description of FIG. 3, the terms used herein are briefly explained.

The term “edge” may indicate the entire region in the rim of the wafer W. In detail, the edge of the wafer W may include the top edge TE, the upper bevel UB, the bevel apex BA, the lower bevel LB, and the bottom edge BE.

The term “bevel” may indicate a region having an outer surface, which is inclined with respect to a horizontal direction, in the entire region of the edge of the wafer W. In detail, the bevel of the wafer W may include the upper bevel UB, the bevel apex BA, and the lower bevel LB. Referring to FIG. 3, the bevel of the wafer W may include the upper bevel UB and the lower bevel LB, each having a round shape, and the bevel apex BA having a flat shape. However, the shape of the bevel of the wafer W in FIG. 3 is just an example. Each of the upper bevel UB, the lower bevel LB, and the bevel apex BA may have a round shape. The bevel of the wafer W may have various shapes. For example, the outer surface of each of the upper bevel UB and the lower bevel LB may have a straight-line shape instead of a curved shape.

An upper edge UE may indicate an edge region in an upper portion of the entire region of the edge of the wafer W. In detail, the upper edge UE of the wafer W may include the top edge TE and the upper bevel UB.

A lower edge LE may indicate an edge region in a lower portion of the entire region of the edge of the wafer W. In detail, the lower edge LE of the wafer W may include the bottom edge BE and the lower bevel LB.

The bevel apex BA may indicate a region located at a middle height of the entire region of the bevel of the wafer W. For example, when the total height of the wafer W is divided into three equal parts, the bevel apex BA may indicate a region located in the middle height part of the wafer W. Although the outer surface of the bevel apex BA has a flat shape in FIG. 3, the outer surface of the bevel apex BA may have various shapes including a round shape.

FIG. 4 is a cross-sectional view illustrating the configuration of the upper optical system 200, according to an implementation.

Referring to FIG. 4, the upper optical system 200 may include an upper coaxial light source 210, an upper non-coaxial light source 220, a first upper mirror 221, an upper detector 230, a second upper mirror 241, an upper lens 242, and an upper beam splitter 243.

The upper coaxial light source 210 may output first upper light to the upper edge of the wafer W in the vertical direction. The first upper light output from the upper coaxial light source 210 may travel along the same axis as the optical axis of the upper detector 230. For example, the upper coaxial light source 210 may be arranged above the wafer W to output the first upper light downward in the vertical direction.

Although FIG. 4 illustrates that the upper coaxial light source 210 is arranged to output the first upper light downward in the vertical direction, this is just an example. It should be noted that the upper coaxial light source 210 may be arranged in various positions such that the first upper light may travel along the same axis as the optical axis of the upper detector 230.

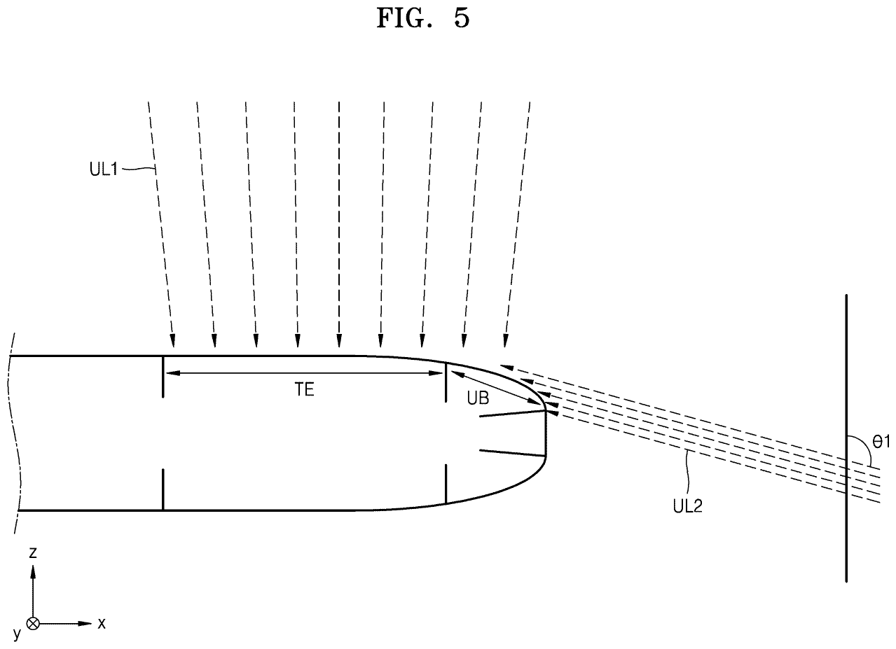

The upper non-coaxial light source 220 may output second upper light that is radiated from the outside of the wafer W to the upper edge of the wafer W at an angle oblique to the vertical direction. The upper non-coaxial light source 220 may be arranged in a different position than the optical axis of the upper detector 230. Light paths of the first upper light and the second upper light to the upper edge of the wafer W are described in detail with reference to FIG. 5 below.

Although FIG. 4 illustrates that the upper non-coaxial light source 220 is arranged to output the second upper light downward in the vertical direction, this is just an example. It is to be understood that the upper non-coaxial light source 220 may be arranged in various positions such that the second upper light may be emitted to the upper edge at an angle oblique to the vertical direction.

As shown in FIG. 4, the upper coaxial light source 210 and the upper non-coaxial light source 220 may output parallel light traveling in parallel in one direction. The upper coaxial light source 210 and the upper non-coaxial light source 220 may be of the same types. Each of the upper coaxial light source 210 and the upper non-coaxial light source 220 may include a light-emitting diode (LED) light source, a halogen lamp, or other various light sources. The first upper light output from the upper coaxial light source 210 and the second upper light output from the upper non-coaxial light source 220 may each include at least one selected from the group consisting of visible light, ultraviolet light, infrared light, etc.

The first upper mirror 221 may radiate the second upper light output from the upper non-coaxial light source 220 to the upper edge of the wafer W. According to an implementation, the first upper mirror 221 may be arranged below the upper non-coaxial light source 220, as shown in FIG. 4. The first upper mirror 221 may be oblique to the vertical direction.

The second upper light may be radiated to the upper edge of the wafer W at a first angle. The first angle may indicate the degree to which the second upper light radiated to the upper edge of the wafer W is inclined with respect to the vertical direction.

According to an implementation, the first angle may be at least 90 degrees. In this case, the first upper mirror 221 may be inclined at half the first angle with respect to the vertical direction. For example, when the first angle is 110 degrees, the first upper mirror 221 may be inclined at 55 degrees with respect to the vertical direction.

According to some implementations, unlike FIG. 4, the upper non-coaxial light source 220 may be at a lower vertical level than the wafer W and may output the second upper light upward in the vertical direction. In this case, the first upper mirror 221 may be arranged at a higher vertical level than the wafer W to be oblique to the vertical direction and may reflect the second upper light output from the upper non-coaxial light source 220 to allow the second upper light to be radiated to the upper edge of the wafer W. At this time, the first angle may be less than 90 degrees. Accordingly, the first upper mirror 221 may be inclined with respect to the vertical direction at an angle obtained by adding 90 degrees to half the first angle. For example, when the first angle is 30 degrees, the first upper mirror 221 may be inclined at 105 degrees with respect to the vertical direction.

However, the arrangement of the upper non-coaxial light source 220 and the first upper mirror 221 is just an example. It is to be understood that the upper non-coaxial light source 220 and the first upper mirror 221 may be arranged in various structures. In some implementations, the first upper mirror 221 may be omitted, and the second upper light output from the upper non-coaxial light source 220 may be directly radiated to the upper edge of the wafer W.

The upper detector 230 may detect the first upper light and the second upper light that are reflected from the upper edge of the wafer W. In other words, the upper detector 230 may detect the first upper light and the second upper light, which are reflected from the upper edge of the wafer W, and may acquire an image of the upper edge of the wafer W. The upper detector 230 may include a charge-coupled device (CCD) camera or a complementary metal-oxide semiconductor (CMOS) image sensor.

The second upper mirror 241, the upper lens 242, and the upper beam splitter 243 may enable the first upper light and the second upper light to be transmitted from the upper edge of the wafer W to the upper detector 230. In detail, the upper beam splitter 243 may transmit the first upper light, which is output from the upper coaxial light source 210, toward the upper lens 142 and may transmit the first upper light and the second upper light, which travel from the upper lens 242 toward the upper detector 230, toward the upper detector 230.

The upper lens 242 may focus the first upper light, which travels toward the second upper mirror 241, on the second upper mirror 241. The upper lens 242 may collimate the first upper light and the second upper light, which travel from the second upper mirror 241 to the upper detector 230, and transmit the first upper light and the second upper light toward the upper beam splitter 243.

The second upper mirror 241 may reflect the first upper light transmitted from the upper lens 242 and radiate the first upper light to the upper edge of the wafer W. The second upper mirror 241 may reflect the first upper light and the second upper light, which are reflected from the upper edge of the wafer W, and transmit the first upper light and the second upper light toward the upper lens 242. As shown in FIG. 4, the second upper mirror 241 may be oblique to the vertical direction. For example, the second upper mirror 241 may be perpendicular to the first upper mirror 221.

The upper optical system 200 may include the components described above and thus acquire an upper image of the upper edge of the wafer W.

Referring to FIG. 4, a rotating stage 510 may be connected to the bottom surface of the chuck 500. The rotating stage 510 and the chuck 500 may have an integral structure, and the rotating stage 510 may provide torque to the chuck 500.

The controller 600 may control the rotating stage 510 to rotate the wafer W placed on the top surface of the chuck 500 and may receive an upper image of the upper edge of the wafer W from the upper detector 230 while the wafer W is rotating.

The upper optical system 200 may acquire an image of the upper edge of the wafer W by using both the first upper light output from the upper coaxial light source 210 and the second upper light output from the upper non-coaxial light source 220, thereby acquiring a high-resolution image of the top edge TE and the upper bevel UB of the wafer W. A region of the wafer W to which the first upper light is radiated and a region of the wafer W to which the second upper light is radiated are described in detail with reference to FIG. 5 below.

FIG. 5 is a cross-sectional view illustrating first upper light and second upper light, according to an implementation.

Referring to FIG. 5, first upper light UL1 and second upper light UL2 may be radiated to the upper edge of the wafer W. The first upper light UL1 may be output from the upper coaxial light source 210, and the second upper light UL2 may be output from the upper non-coaxial light source 220.

Referring to FIG. 5, the first upper light UL1 may be radiated from above the wafer W to the upper edge of the wafer W in the vertical direction. The expression “light is radiated in the vertical direction” used herein may mean that light is radiated in a direction that is substantially perpendicular to the horizontal direction. “Being substantially perpendicular to the horizontal direction” may refer to not only “inclined at 90 degrees with respect to the horizontal direction” but also “inclined at nearly 90 degrees with respect to the horizontal direction”. For example, when light is radiated at an angle of about 85 degrees to about 95 degrees to the horizontal direction, the expression “light is radiated in the vertical direction” may be used herein.

The first upper light UL1 may be radiated to the upper edge of the wafer W in the vertical direction and thus be used to detect the top edge TE having a flat outer surface. However, the first upper light UL1 radiated in the vertical direction may be unsuitable to detect the upper bevel UB having an outer surface oblique to the horizontal direction.

For example, when the second upper light UL2 is not radiated, an upper image acquired by the upper detector 230 may include only data of the top edge TE but not data of the upper bevel UB.

The second upper light UL2 may be radiated to the upper edge of the wafer W at a first angle θ1 inclined with respect to the vertical direction. The first angle θ1 may be about 30 degrees to about 130 degrees. The second upper light UL2 that is radiated to the upper edge of the wafer W at the first angle θ1 inclined with respect to the vertical direction may be used to detect the upper bevel UB. However, the second upper light UL2 may be unsuitable to detect the top edge TE having the flat outer surface. Accordingly, when the first upper light UL1 and the second upper light UL2 are simultaneously used, both data of the top edge TE and data of the upper bevel UB may be included in an upper image acquired by the upper detector 230.

When the first angle θ1 is small, the overall brightness value of the outer surface of the upper bevel UB may appear high in an upper image acquired by the upper detector 230. Contrarily, data of a lower outer surface of the upper bevel UB may not be included in the upper image. When the first angle θ1 is large, the data of the lower outer surface of the upper bevel UB may be included in an upper image acquired by the upper detector 230 while the overall brightness value of the outer surface of the upper bevel UB may be low.

For example, it may be assumed that the first angle θ1 is 30 degrees, that is, the second upper light UL2 is radiated to the upper edge at 30 degrees inclined with respect to the vertical direction. In this case, the brightness value of an upper portion of the outer surface of the upper bevel UB may appear high in an upper image acquired by the upper detector 230. Data of a lower portion of the outer surface of the upper bevel UB may not be included in the upper image.

Contrarily, it may be assumed that the first angle θ1 is 130 degrees. In this case, data of a lower portion of the outer surface of the upper bevel UB may be included in an upper image acquired by the upper detector 230 while the overall brightness value of the outer surface of the upper bevel UB may appear low. In other words, the data of the outer surface of the upper bevel UB may be obtained, but brightness may be too low to detect a defect.

It may be most desirable for the first angle θ1 to be 110 degrees. When the first angle θ1 is 110 degrees, both the data of the upper outer surface of the upper bevel UB and the data of the lower outer surface of the upper bevel UB may be included in the upper image, and the overall brightness value of the outer surface of the upper bevel UB may be sufficiently high. Here, that the overall brightness value is sufficiently high may mean that an image is bright enough to detect a defect in the upper bevel UB.

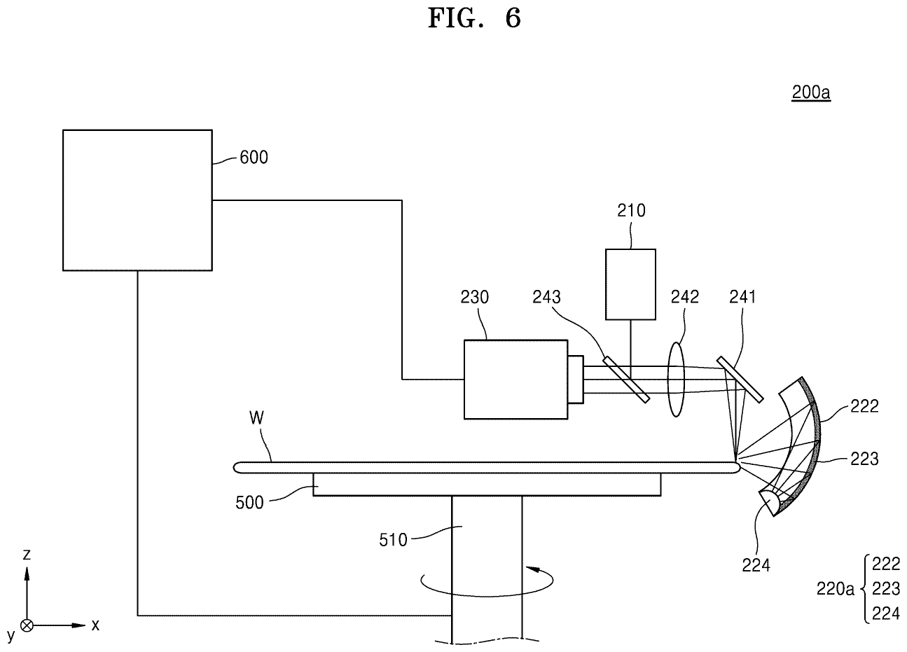

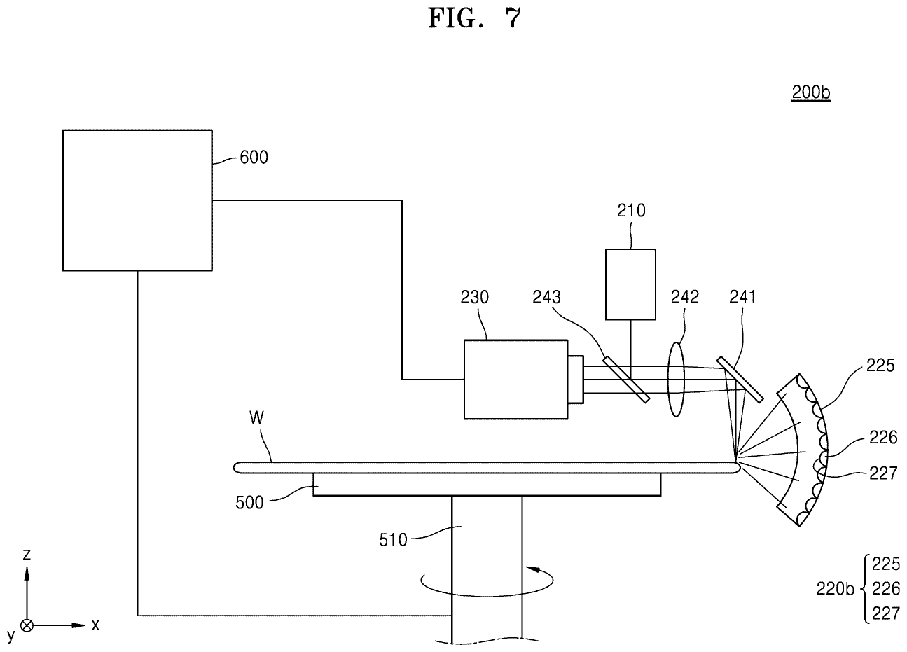

As described above, according to an implementation, the wafer inspection apparatus 1000 may use the second upper light UL2 that is radiated from the outside of the wafer W to the upper edge of the wafer W at an inclination with respect to the vertical direction, thereby increasing an image coverage for the upper edge of the wafer W. The second upper light UL2 may be radiated to the upper edge of the wafer W at various angles, which is described in detail with reference to FIGS. 6 and 7 below.

FIG. 6 is a cross-sectional view illustrating the configuration of an upper optical system 200a, according to an implementation. Redundant descriptions given above with reference to FIG. 4 are omitted from the descriptions of FIG. 6, and the differences from the upper optical system 200 of FIG. 4 are mainly described.

Referring to FIG. 6, the upper optical system 200a may include an upper non-coaxial light source 220a. The upper non-coaxial light source 220a may include a reflective upper structure 222, a diffuse reflection coating film 223, and at least one upper LED 224.

The reflective upper structure 222 may include a curved structure having a sidewall formed as a curved surface. The reflective upper structure 222 may include a first sidewall, a second sidewall, and a certain inner space between the first sidewall and the second sidewall. The first sidewall and the second sidewall may be curved. The first sidewall may be closer to the wafer W than the second sidewall, and the second sidewall may be farther apart from the wafer W than the first sidewall.

For example, as shown in FIG. 6, the first sidewall and the second sidewall of the reflective upper structure 222 may have the same center of curvature. In this case, the radius of curvature of the second sidewall may be greater than the radius of curvature of the first sidewall.

The diffuse reflection coating film 223 may be on the second sidewall of the reflective upper structure 222. In detail, the diffuse reflection coating film 223 may be bonded to the inside of the second sidewall of the reflective upper structure 222. The diffuse reflection coating film 223 may have a surface having fine roughness. The diffuse reflection coating film 223 may diffusely reflect second upper light emitted from the upper LED 224.

According to an implementation, the diffuse reflection coating film 223 may have a surface composed of nano particles or micro particles. The nano particles or micro particles of the diffuse reflection coating film 223 may include silicon dioxide (SiO₂) particles, polymer particles, metal particles, metal oxide particles, etc. For example, the surface of the diffuse reflection coating film 223 may be composed of titanium oxide (TiO₂) particles.

The upper LED 224 may be arranged on the bottom surface of the reflective upper structure 222. The upper LED 224 may output the second upper light to the diffuse reflection coating film 223. The second upper light output from the upper LED 224 may be diffusely reflected by the diffuse reflection coating film 223.

The second upper light diffusely reflected by the diffuse reflection coating film 223 may be radiated to the upper edge of the wafer W at various angles. For example, the second upper light may be radiated to the upper edge of the wafer W at an angle of about 30 degrees to about 130 degrees with respect to the vertical direction. The second upper light may be radiated to the upper edge of the wafer W at various angles. For example, the second upper light may be radiated to the upper edge of the wafer W at an angle of about 20 degrees to about 140 degrees with respect to the vertical direction.

FIG. 7 is a cross-sectional view illustrating the configuration of an upper optical system 200b, according to an implementation. Redundant descriptions given above with reference to FIG. 4 are omitted from the descriptions of FIG. 7, and the differences from the upper optical system 200 of FIG. 4 are mainly described.

Referring to FIG. 7, the upper optical system 200b may include an upper non-coaxial light source 220b. The upper non-coaxial light source 220b may include a transmissive upper structure 225, at least one upper LED 226, and an upper diffuser 227.

The transmissive upper structure 225 may have a shape that is the same as or similar to the shape of the reflective upper structure 222 described above with reference to FIG. 6. The transmissive upper structure 225 may include a first sidewall, which is relative close to the wafer W, and a second sidewall, which is farther apart from the wafer W than the first sidewall. The first sidewall and the second sidewall of the transmissive upper structure 225 may have the same center of curvature.

The at least one upper LED 226 may be arranged on the second sidewall of the transmissive upper structure 225. The at least one upper LED 226 may output second upper light. As shown in FIG. 7, the at least one upper LED 226 may be implemented as an LED array including a plurality of LEDs. For example, the at least one upper LED 226 may correspond to an LED array including 100*1000 LEDs on the inside of the second sidewall.

The at least one upper LED 226 may be arranged in a C-shape on the inside of the second sidewall. In detail, the at least one upper LED 226 may be arranged in a C-shape along the inside of the second sidewall and may face the upper edge of the wafer W.

The upper diffuser 227 may be arranged in front of (e.g., in an optical path of) the at least one upper LED 226 and may diffuse the second upper light output from the at least one upper LED 226. The second upper light passing through the upper diffuser 227 may be scattered at various angles. The upper diffuser 227 may include a light-transmitting layer and micro particles in the light-transmitting layer. The micro particles of the upper diffuser 227 may scatter light. The micro particles may include acrylic particles, silicon dioxide particles, titanium oxide particles, etc. For example, the upper diffuser 227 may be formed as a film attached to the front side of the at least one upper LED 226. Alternatively, the upper diffuser 227 may be formed as a film attached to the first sidewall of the transmissive upper structure 225.

The second upper light scattered by the upper diffuser 227 may be radiated to the upper edge of the wafer W at various angles. For example, the second upper light may be radiated to the upper edge of the wafer W at an angle of about 30 degrees to about 130 degrees with respect to the vertical direction.

As described above with reference to FIGS. 6 and 7, the upper optical system 200 according to an implementation may include the upper non-coaxial light source 220 that may be implemented in various configurations and structures, thereby increasing an image coverage for the upper edge UE of the wafer W. The configuration of the lower optical system 300, which is located in a position symmetrical with the upper optical system with respect to the center of the chuck 500, is described in detail with reference to FIG. 8 below.

FIG. 8 is a cross-sectional view illustrating the configuration of the lower optical system 300, according to an implementation.

Referring to FIG. 8, the lower optical system 300 may include a lower coaxial light source 310, a lower non-coaxial light source 320, a first lower mirror 321, a lower detector 330, a second lower mirror 341, a lower lens 342, and a lower beam splitter 343.

The lower coaxial light source 310, the lower non-coaxial light source 320, the first lower mirror 321, the lower detector 330, the second lower mirror 341, the lower lens 342, and the lower beam splitter 343 may be arranged in positions respectively symmetrical with the upper coaxial light source 210, the upper non-coaxial light source 220, the first upper mirror 221, the upper detector 230, the second upper mirror 241, the upper lens 242, and the upper beam splitter 243, which have been described with reference to FIG. 4 above, with respect to the center of the chuck 500. For example, the lower coaxial light source 310 may be arranged in a position symmetrical with the upper coaxial light source 210 with respect to the center of the chuck 500, and the lower non-coaxial light source 320 may be arranged in a position symmetrical with the upper non-coaxial light source 220 with respect to the center of the chuck 500

Although the components of the lower optical system 300 may be distinguished from the components of the upper optical system 200 acquiring an image of the upper edge UE of the wafer W in that the components of the lower optical system 300 are configured to acquire an image of the lower edge LE of the wafer W, the components of the lower optical system 300 may operate based on structures and methods that are the same as or similar to those of the components of the upper optical system 200.

The lower coaxial light source 310 may output first lower light to the lower edge of the wafer W in the vertical direction. The first lower light output from the lower coaxial light source 310 may travel along the same axis as the optical axis of the lower detector 330. For example, the lower coaxial light source 310 may be arranged below the wafer W to output the first lower light upward in the vertical direction.

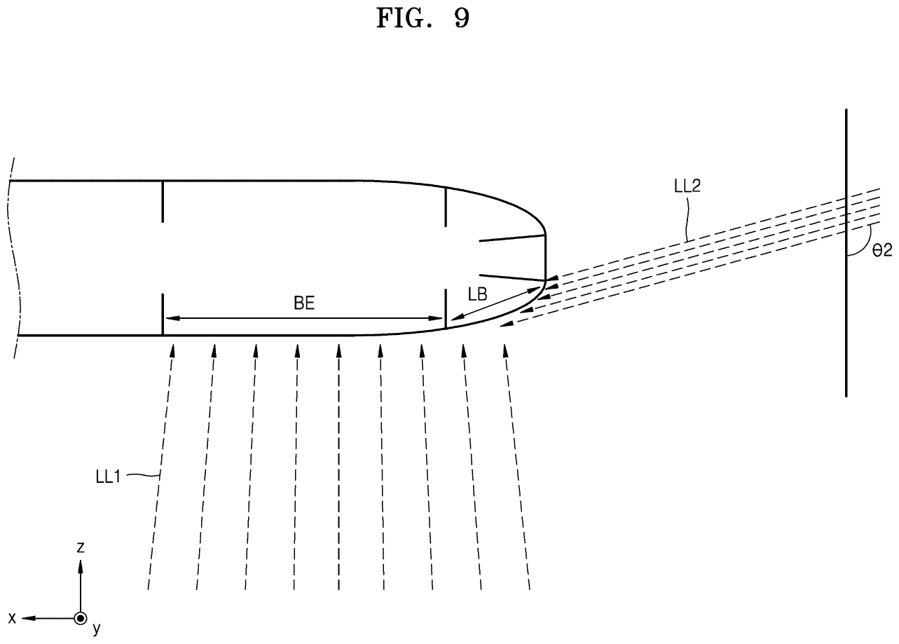

The lower non-coaxial light source 320 may output second lower light that is radiated from the outside of the wafer W to the lower edge of the wafer W at an angle oblique to the vertical direction. The lower non-coaxial light source 320 may be arranged in a different position than the optical axis of the lower detector 330. Light paths of the first lower light and the second lower light to the lower edge of the wafer W are described in detail with reference to FIG. 9 below.

The first lower mirror 321 may radiate the second lower light output from the lower non-coaxial light source 320 to the lower edge of the wafer W. According to an implementation, the first lower mirror 321 may be arranged above the lower non-coaxial light source 320, as shown in FIG. 8, and may be oblique to the vertical direction.

The second lower light may be radiated to the lower edge of the wafer W at a second angle. The second angle may indicate the degree to which the second lower light radiated to the lower edge of the wafer W is inclined with respect to the vertical direction.

According to some implementations, unlike FIG. 8, the lower non-coaxial light source 320 may be located at a higher vertical level than the wafer W and may output the second lower light downward in the vertical direction. In this case, the first lower mirror 321 may be arranged at a lower vertical level than the wafer W to be oblique to the vertical direction and may reflect the second lower light output from the lower non-coaxial light source 320 to allow the second lower light to be radiated to the lower edge of the wafer W.

The lower detector 330 may detect the first lower light and the second lower light that are reflected from the lower edge of the wafer W. In other words, the lower detector 330 may detect the first lower light and the second lower light, which are reflected from the lower edge of the wafer W, and may acquire an image of the lower edge of the wafer W. The lower detector 330 may include a CCD camera or a CMOS image sensor.

The second lower mirror 341, the lower lens 342, and the lower beam splitter 343 may enable the first lower light and the second lower light to be transmitted from the lower edge of the wafer W to the lower detector 330.

A region of the wafer W to which the first lower light is radiated and a region of the wafer W to which the second lower light is radiated are described in detail with reference to FIG. 9 below.

FIG. 9 is a cross-sectional view illustrating first lower light and second lower light, according to an implementation.

Referring to FIG. 9, first lower light LL1 and second lower light LL2 may be radiated to the lower edge of the wafer W. The first lower light LL1 may be output from the lower coaxial light source 310, and the second lower light LL2 may be output from the lower non-coaxial light source 320.

The first lower light LL1 may be radiated from below the wafer W to the lower edge of the wafer W in the vertical direction. The first lower light LL1 may be radiated to the lower edge of the wafer W in the vertical direction and thus be used to detect the bottom edge BE having a flat outer surface. However, the first lower light LL1 radiated in the vertical direction may be unsuitable to detect the lower bevel LB having an outer surface oblique to the horizontal direction.

For example, when the second lower light LL2 is not radiated, a lower image acquired by the lower detector 330 may include only data of the bottom edge BE but not data of the lower bevel LB.

The second lower light LL2 may be radiated to the lower edge of the wafer W at a second angle θ2 inclined with respect to the vertical direction. The second angle θ2 may be about 30 degrees to about 130 degrees. The second lower light LL2 that is radiated to the lower edge of the wafer W at the second angle θ2 inclined with respect to the vertical direction may be used to detect the lower bevel LB.

As described above with reference to FIG. 5, it may be most desirable for the second angle θ2 to be 110 degrees. When the second angle θ2 is 110 degrees, both the data of the upper outer surface of the lower bevel LB and the data of the lower outer surface of the lower bevel LB may be included in the lower image, and the overall brightness value of the outer surface of the lower bevel LB may be sufficiently high.

As described above, according to an implementation, the wafer inspection apparatus 1000 may use the second lower light LL2 that is radiated from the outside of the wafer W to the lower edge of the wafer W at an inclination with respect to the vertical direction, thereby increasing an image coverage for the lower edge of the wafer W. The second lower light LL2 may be radiated to the lower edge of the wafer W at various angles.

According to an implementation, the lower non-coaxial light source 320 may be formed as a reflective lower structure, which includes at least one lower LED and a diffuse reflection coating film. The reflective lower structure, which includes the lower LED and the diffuse reflection coating film, may be arranged in a position symmetrical with the reflective upper structure 222, which has been described above with reference to FIG. 6, with respect to the center of the chuck 500. The lower LED and the diffuse reflection coating film of the reflective lower structure may be arranged in positions respectively symmetrical with the upper LED 224 and the diffuse reflection coating film 223 with respect to the center of the chuck 500 and may respectively perform the same functions as the upper LED 224 and the diffuse reflection coating film 223.

The lower coaxial light source 310 may be formed as a transmissive lower structure including at least one lower LED and a lower diffuser. The transmissive lower structure, which includes the lower LED and the lower diffuser, may be arranged in a position symmetrical with the transmissive upper structure 225, which has been described above with reference to FIG. 7, with respect to the center of the chuck 500. The lower LED and the lower diffuser of the transmissive lower structure may be arranged in positions respectively symmetrical with the upper LED 226 and the upper diffuser 227 with respect to the center of the chuck 500 and may respectively perform the same functions as the upper LED 226 and the upper diffuser 227.

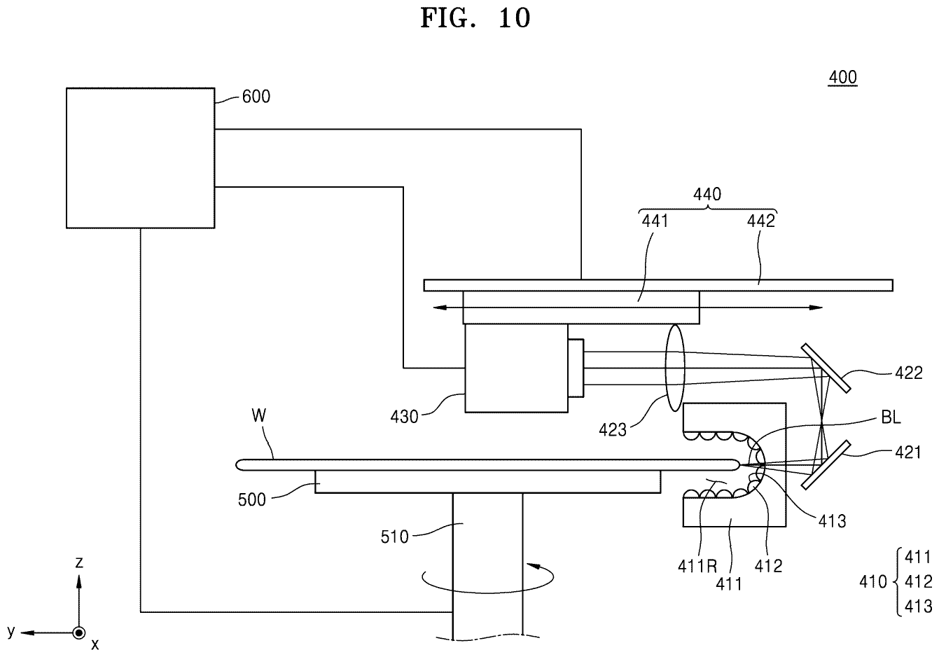

As described above, the lower non-coaxial light source 320 may include the reflective lower structure or the transmissive lower structure, each having a curved surface, thereby radiating the second lower light to the lower edge of the wafer W at various angles. Accordingly, an image coverage for the lower edge of the wafer W may be increased. A method of acquiring, by the bevel optical system 400, a bevel image is described with reference to FIG. 10 below.

FIG. 10 is a cross-sectional view illustrating the configuration of the bevel optical system 400, according to an implementation.

Referring to FIG. 10, the bevel optical system 400 may include a bevel light source 410, a first bevel mirror 421, a second bevel mirror 422, a bevel lens 423, a bevel detector 430, and a linear stage 440.

The bevel light source 410 may include a bevel structure 411, a plurality of bevel LEDs 412, and a bevel diffuser 413. The bevel structure 411 may include a recess 411R. The recess 411R may extend from a sidewall of the bevel structure 411 to the inside of the bevel structure 411.

The recess 411R may have a shape corresponding to the edge of the wafer W. As shown in FIG. 3, the edge of the wafer W may include the top edge TE and the bottom edge BE, each having the outer surface parallel with the horizontal direction, and a bevel having the outer surface oblique to the horizontal direction. The recess 411R may also have an outer surface parallel with the horizontal direction and a round outer surface oblique to the horizontal direction. In detail, the top and bottom surfaces of the recess 411R may be parallel with the horizontal direction. The side surface of the recess 411R may have a round shape oblique to the horizontal direction.

The recess 411R may be arranged outside the bevel of the wafer W to be apart from the bevel of the wafer W and may surround the outer surface of the bevel of the wafer W. In other words, the recess 411R may be arranged to surround the outer surface of the bevel of the wafer W.

The bevel LEDs 412 may form an LED array and may be arranged in a U-shape on the surface of the recess 411R. The bevel LEDs 412 may be arranged to output bevel light BL toward the bevel of the wafer W. As the bevel LEDs 412 are arranged in a U-shape on the recess 411R to face the bevel of the wafer W, the bevel light BL may be radiated to the bevel of the wafer W at various angles. Accordingly, it may be easy to acquire a high-resolution image of the bevel apex BA of the wafer W.

The bevel diffuser 413 may be arranged in front of the bevel LEDs 412. The bevel diffuser 413 may include a light-transmitting layer and micro particles in the light-transmitting layer. The micro particles of the bevel diffuser 413 may diffuse the bevel light BL output from the bevel LEDs 412. The micro particles may include acrylic particles, silicon dioxide particles, titanium oxide particles, etc.

The bevel light BL diffused by the bevel diffuser 413 may be radiated to the bevel apex BA of the wafer W at various angles. For example, the bevel light BL passing through the bevel diffuser 413 may be radiated to the bevel apex BA of the wafer W at an angle of about 30 degrees to about 150 degrees with respect to the vertical direction.

The first bevel mirror 421 and the second bevel mirror 422 may transmit the bevel light BL reflected from the bevel apex BA of the wafer W toward the bevel lens 423. The first bevel mirror 421 and the second bevel mirror 422 may be apart from the bevel light source 410 in the second horizontal direction. In detail, the bevel light source 410 may be apart from the bevel apex BA, to which the bevel light BL is radiated, in the +X direction, and the first bevel mirror 421 and the second bevel mirror 422 may be apart from the bevel apex BA, to which the bevel light BL is radiated, in the −X direction which is opposite direction to the +X direction. The second bevel mirror 422 may be at a higher vertical level than the first bevel mirror 421. The first bevel mirror 421 and the second bevel mirror 422 may be oblique to the vertical direction.

The bevel light BL reflected from the bevel apex BA of the wafer W may be reflected by the first bevel mirror 421 to be transmitted toward the second bevel mirror 422. The bevel light BL transmitted toward the second bevel mirror 422 may be reflected by the second bevel mirror 422 to be transmitted toward the bevel lens 423. According to an implementation, the first bevel mirror 421 and the second bevel mirror 422 may be perpendicular to each other. Accordingly, the light path of the bevel light BL traveling from the bevel apex BA of the wafer W to the first bevel mirror 421 may be parallel with the light path of the bevel light BL traveling from the second bevel mirror 422 to the bevel lens 423. The bevel lens 423 may collimate the bevel light BL reflected by the second bevel mirror 422 and transmit the bevel light BL to the bevel detector 430.

The bevel detector 430 may detect the bevel light BL reflected from the bevel apex BA of the wafer W. In other words, the bevel detector 430 may acquire an image of the bevel apex BA of the wafer W by detecting the bevel light BL reflected from the bevel apex BA of the wafer W. The bevel detector 430 may include a CCD camera or a CMOS image sensor.

The linear stage 440 may include a slider 441 and a linear actuator 442. The linear stage 440 may move the bevel lens 423 and the bevel detector 430 in the horizontal direction to adjust the horizontal distance between the bevel lens 423 and each of the first bevel mirror 421 and the second bevel mirror 422.

Referring back to FIG. 1, it may be very difficult for the transfer robot 2100 to place the wafer W so that the wafer W is exactly aligned with the center of the chuck 500 Accordingly, an alignment error may be bound to occur in the position of the wafer W placed by the transfer robot 2100 on the top surface of the chuck 500. Here, “alignment error” may mean that the wafer W is placed such that the center of the wafer W does not coincide with the center of the chuck 500 and may include an eccentricity in the first horizontal direction and an eccentricity in the second horizontal direction.

As described above, when an alignment error occurs with respect to the wafer W, the clarity of a bevel image detected by the bevel detector 430 may be reduced. To acquire a high-resolution bevel image, the depth of field (DoF) of the bevel detector 430 may be very small. Accordingly, even when there is a very small alignment error, the bevel detector 430 may acquire a bevel image having poor clarity.

For example, when the wafer W is placed with an eccentricity of about 30 μm from the center of the chuck 500 in the first horizontal direction (e.g., the +Y direction), the bevel detector 430 may acquire a bevel image having poor clarity. The bevel image acquired by the bevel detector 430 may include data of only a very small portion of the entire area of the bevel apex BA of the wafer W.

To compensate for the alignment error of the wafer W described above, the linear stage 440 may receive a control signal from the controller 600 and move the bevel detector 430 and the bevel lens 423 in the horizontal direction.

The slider 441 may be coupled to the bevel detector 430 and the bevel lens 423. The slider 441 may also be coupled to the linear actuator 442 so that the slider 441 may receive power from the linear actuator 442 and move in the horizontal direction with respect to the linear actuator 442. Although FIG. 10 shows that one slider 441 is coupled to the bevel detector 430 and the bevel lens 423, two sliders 441 may each be coupled to the bevel detector 430 and the bevel lens 423.

The linear actuator 442 may be fixed to the inner wall of a housing of the wafer inspection apparatus 1000 and may provide power so that the slider 441 may move in the horizontal direction. The linear actuator 442 may include a linear movement guide such that the slider 441 may move in the horizontal direction along the linear movement guide.

According to an implementation, the linear stage 440 may move the bevel lens 423 and the bevel detector 430 such that the distance between the bevel lens 423 and the bevel detector 430 is maintained constant and the distance between the bevel lens 423 and the second bevel mirror 422 and the distance between the bevel detector 430 and the second bevel mirror 422 are changed.

Although it has been described with reference to FIG. 10 that the linear stage 440 includes the slider 441 and the linear actuator 442 to move the bevel detector 430 and the bevel lens 423 in the horizontal direction, It is to be understood that the linear stage 440 may include various configurations and structures for moving the bevel detector 430 and the bevel lens 423 in the horizontal direction.

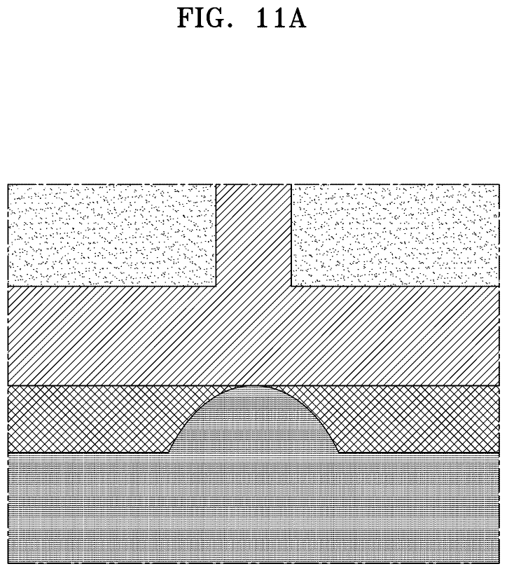

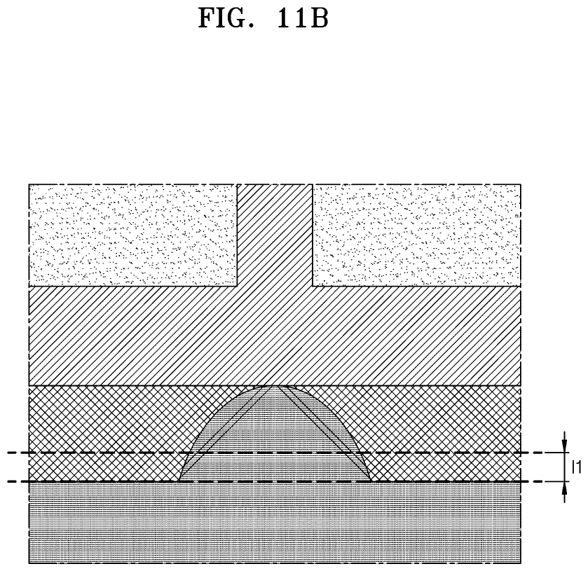

As described above, the bevel optical system 400 may include the bevel light source 410, which may radiate the bevel light BL to the bevel apex BA of the wafer W at various angles, and the linear stage 440, which may move the bevel lens 423 and the bevel detector 430 in the horizontal direction, thereby acquiring a high-resolution bevel image of the bevel apex BA of the wafer W. The effects of a plurality of optical systems according to an implementation are described in detail with reference to FIGS. 11A to 13B below.

FIGS. 11A and 11B show upper images acquired by an upper optical system, according to an implementation.

FIG. 11A shows a first upper image acquired by the upper optical system 200 that does not include the upper non-coaxial light source 220. FIG. 11B shows a second upper image acquired by the upper optical system 200 that includes the upper non-coaxial light source 220.

Referring to FIGS. 11A and 11B, it may be seen that the image coverage of the second upper image is greater than that of the first upper image. In detail, the first upper image may include only the data of the top edge TE of the wafer W but not the data of the upper bevel UB of the wafer W. Contrarily, it may be seen that the second upper image may include the data of the upper bevel UB of the wafer W and that the visibility of the upper bevel UB of the wafer W is secured by a first distance l1. Here, the first distance l1 may be about 300 μm to about 600 μm.

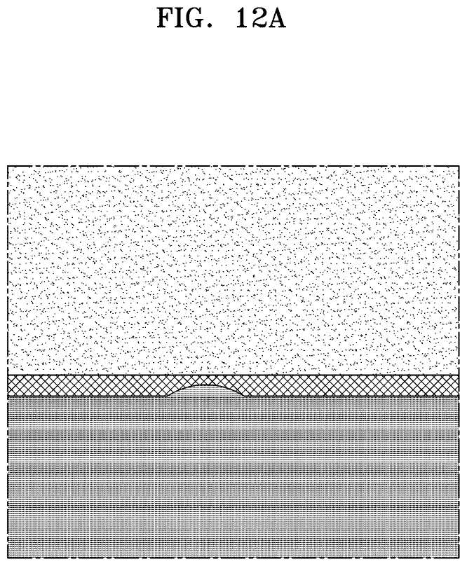

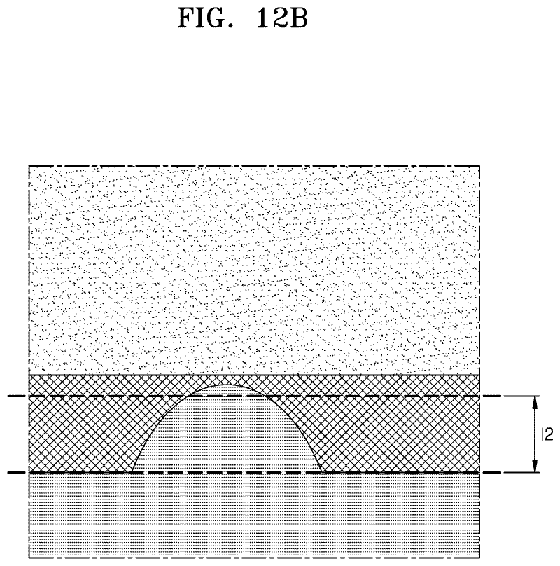

FIGS. 12A and 12B show lower images acquired by a lower optical system, according to an implementation.

FIG. 12A shows a first lower image acquired by the lower optical system 300 that does not include the lower non-coaxial light source 320. FIG. 12B shows a second lower image acquired by the lower optical system 300 that includes the lower non-coaxial light source 320.

Referring to FIGS. 12A and 12B, it may be seen that the image coverage of the second lower image is greater than that of the first lower image. In detail, the first lower image may include only the data of the bottom edge BE of the wafer W but not the data of the lower bevel LB of the wafer W. Contrarily, it may be seen that the second lower image may include the data of the lower bevel LB of the wafer W and that the visibility of the lower bevel LB of the wafer W is secured by a first distance l2. Here, the second distance l2 may be about 600 μm to about 100 mm.

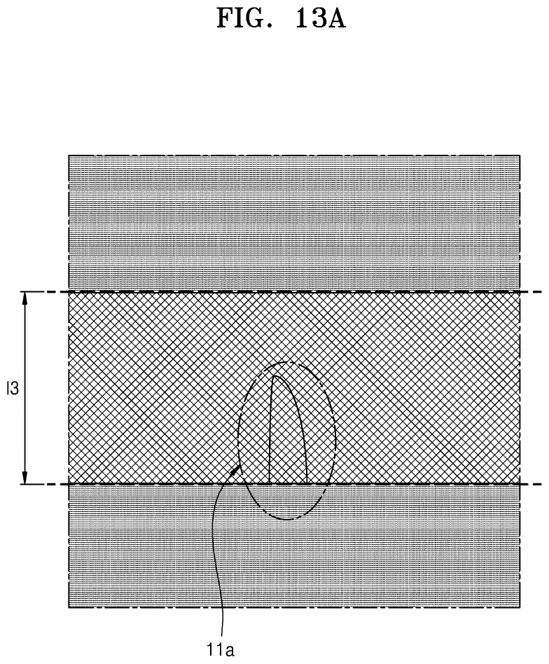

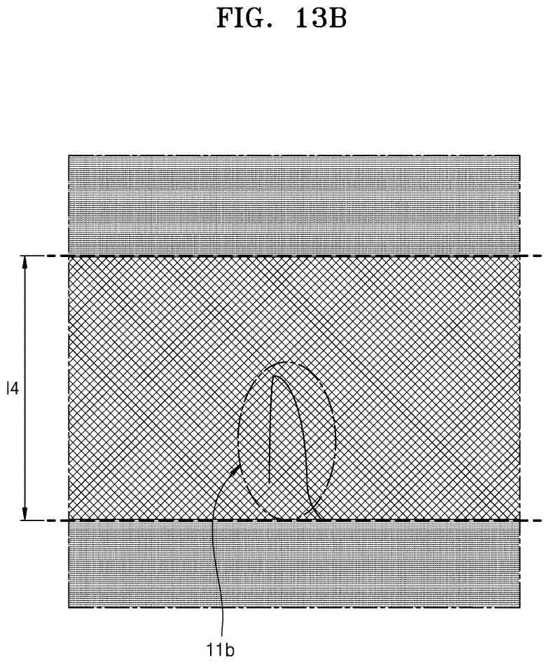

FIGS. 13A and 13B show bevel images acquired by a bevel optical system, according to an implementation.

FIG. 13A shows a first bevel image acquired by the bevel optical system 400 when parallel light is incident to the bevel apex BA of the wafer W. FIG. 13B shows a second bevel image acquired by the bevel optical system 400 that includes the bevel light source 410.

Referring to FIGS. 13A and 13B, it may be seen that the image coverage of the second bevel image is greater than that of the first bevel image. It may be seen that there is a dark region in the first bevel image. The dark region in the first bevel image may correspond to a region including a curved surface of the bevel of the wafer W. Contrarily, it may be seen that there is no significant dark region in the second bevel image. It may also be seen that while the region of the bevel apex BA of the wafer W is displayed by a third distance l3 in the first bevel image, the region of the bevel apex BA of the wafer W is displayed by a fourth distance l4 in the second bevel image, wherein the fourth distance l4 is greater than the third distance l3.

It may also be seen that the second bevel image has high visibility of a defect. A defect 11a in the first bevel image may be difficult to observe, whereas a defect 11b in the second bevel image may be clearly observed due to the contrast between the defect 11b and the surroundings.

As may be seen in FIGS. 11A to 13B, the wafer inspection apparatus 1000 according to the present disclosure may include the upper optical system, the bevel optical system 400, and the lower optical system 300 respectively specialized for the upper edge UE, the bevel apex BA, and the lower edge LE of the wafer W. Accordingly, the wafer inspection apparatus 1000 may acquire high-resolution images of the upper edge UE, the bevel apex BA, and the lower edge LE, respectively, and may easily detect a defect, such as chipping or a scratch, based on the acquired images.

However, an operation of compensating for an alignment error of the wafer W may be required to allow the bevel optical system 400 to acquire a clear bevel image. A control operation by the controller 600 to compensate for an alignment error of the wafer W is described in detail with reference to the drawings described below.

FIG. 14 is a flowchart of a method of compensating, by a wafer inspection apparatus, for a wafer alignment error, according to an implementation. FIGS. 1 to 10 are also referred to.

A method of compensating for a wafer alignment error may include acquiring a first edge image from an alignment detector and a second edge image from the upper detector 230 in operation S1100 (hereinafter, referred to as a first operation).

The first operation may be performed after the transfer robot 2100 places the wafer W on the top surface of the chuck 500. In detail, when it is identified that the wafer W is placed on the top surface of the chuck 500, the controller 600 may acquire the first edge image from the alignment detector and the second edge image from the upper detector 230 before driving the rotating stage 510. As shown in FIG. 2, when the alignment optical system 100 is at 12 o'clock of the center of the chuck 500 and the upper optical system 200 is at 3 o'clock of the center of the chuck 500, the first edge image may be obtained by capturing an edge region of the wafer W at 12 o'clock of the wafer W and the second edge image may be obtained by capturing an edge region of the wafer W at 3 o'clock of the wafer W. The first edge image and the second edge image may each correspond to a line scan image or an area scan image.

Subsequently, an eccentricity in the first horizontal direction may be identified based on the first edge image and an eccentricity in the second horizontal direction may be identified based on the second edge image, in operation S1200 (hereinafter, referred to as a second operation).

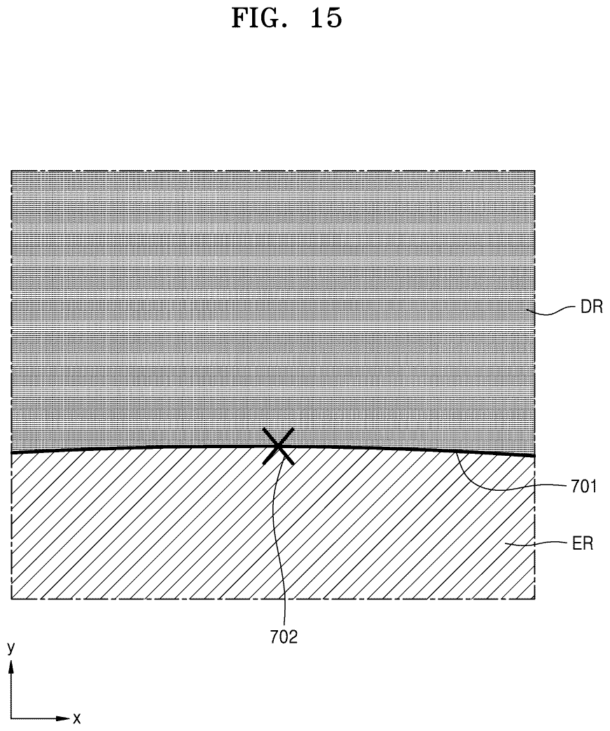

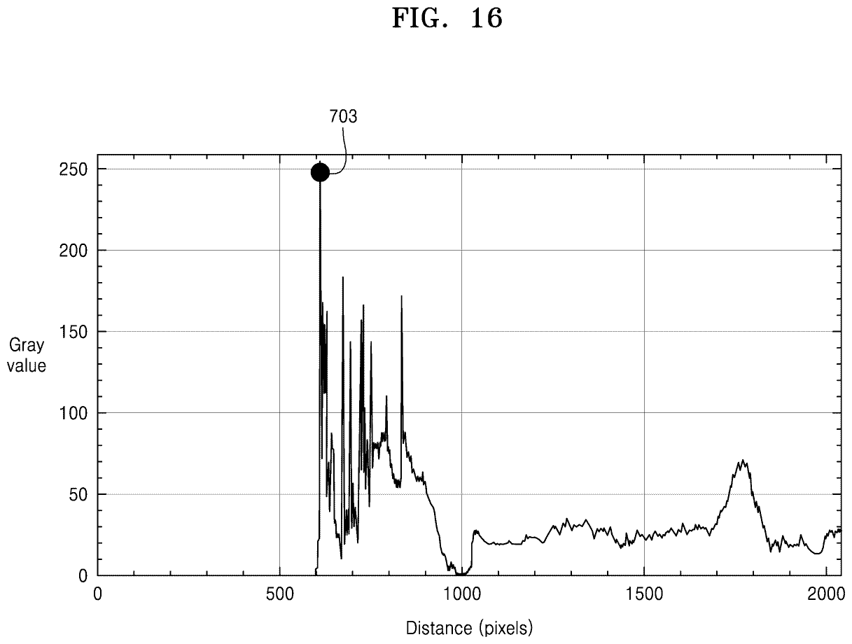

In the second operation, the controller 600 may identify the eccentricity in the first horizontal direction based on the first edge image and the eccentricity in the second horizontal direction based on the second edge image. A method of identifying, by the controller 600, an eccentricity in the first horizontal direction and an eccentricity in the second horizontal direction is described in detail with reference to FIGS. 15 and 16 below.

Subsequently, an expected rotation trajectory of the wafer W may be identified based on the eccentricity in the first horizontal direction and the eccentricity in the second horizontal direction in operation S1300 (hereinafter, referred to as a third operation).

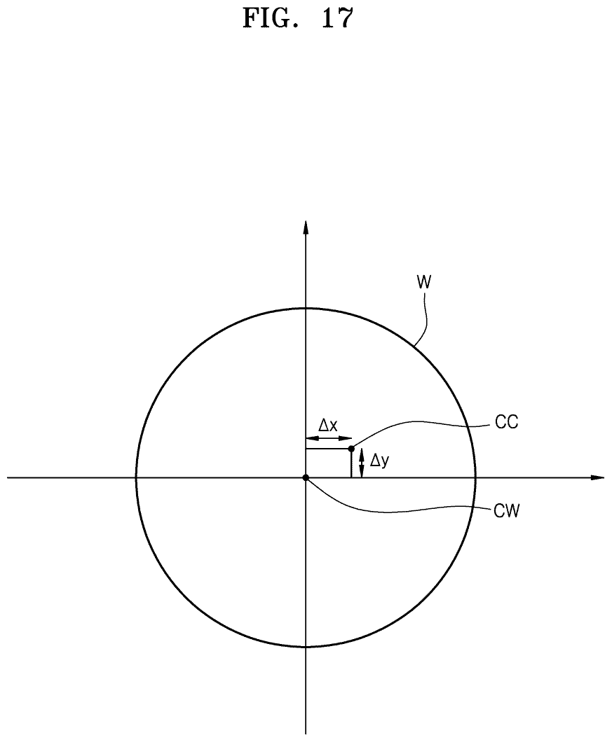

In the third operation, the controller 600 may identify the expected rotation trajectory of the wafer W based on the eccentricity in the first horizontal direction and the eccentricity in the second horizontal direction. In detail, the controller 600 may identify how much the center of the wafer W is eccentric from the center of the chuck 500 and may predict a trajectory, in which the edge of the wafer W rotate, based on the identified eccentricity. This is described in detail with reference to FIG. 17 below.

Subsequently, the wafer W may be pre-rotated, and an edge scan image may be acquired based on the expected rotation trajectory of the wafer W during the pre-rotation of the wafer W, in operation S1400 (hereinafter, referred to as a fourth operation). Based on the edge scan image, a plurality of precision movement amounts respectively corresponding to a plurality of wafer rotation angles may be identified in operation S1500 (hereinafter, referred to as a fifth operation). The pre-rotation can also be referred to as first rotation in the present disclosure.

In the fourth operation, the controller 600 may control the rotating stage 510 to pre-rotate the wafer W and may acquire the edge scan image based on the expected rotation trajectory of the wafer W during the pre-rotation of the wafer W. In the fifth operation, the controller 600 may identify the precision movement amounts respectively corresponding to the wafer rotation angles, based on the edge scan image.

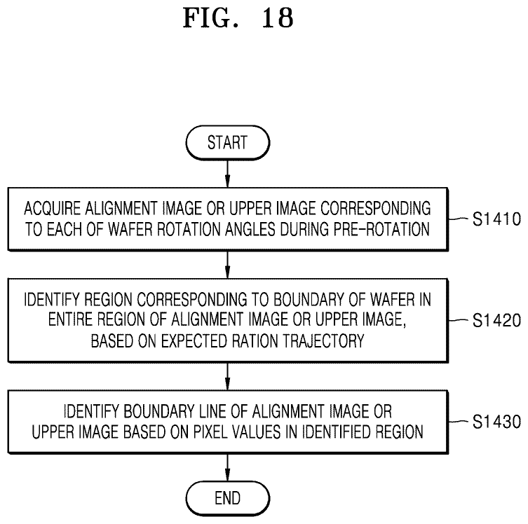

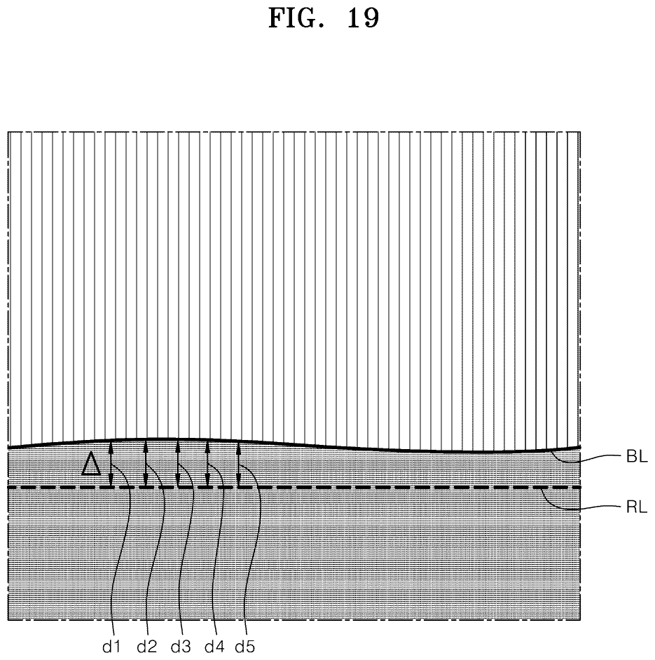

Here, the “pre-rotation of the wafer” may be a concept contrasting with the “main rotation of the wafer”. In detail, the pre-rotation of the wafer may be performed before the main rotation of the wafer to identify how much the bevel detector 430 and the bevel lens 423 need to be moved to compensate for a wafer alignment error and may refer to an operation of rotating the wafer W once with the center of the chuck 500 as the rotation axis. The main rotation of the wafer may refer to an operation of rotating the wafer W once with the center of the chuck 500 as the rotation axis to acquire an image of the edge of the wafer W. The edge scan image may refer to an image acquired by continuously photographing the edge of the wafer W from one spot while the wafer W rotates once. The edge scan image may include a boundary line and a reference line and may be acquired by the alignment detector, the upper detector 230, or the lower detector 330. Specific control operations performed in the fourth operation and the fifth operation are described in detail with reference to FIGS. 18 and 19 below.

Subsequently, the main rotation of the wafer W may be started, and the bevel lens 423 and the bevel detector 430 may be moved in the horizontal direction by each of the precision movement amounts during the main rotation of the wafer W, in operation S1600 (hereinafter, referred to as a sixth operation).

In the sixth operation, the controller may control the rotating stage 510 such that the wafer W performs main rotation and may control the linear stage 440 such that the bevel lens 423 and the bevel detector 430 move in the horizontal direction by each of the precision movement amounts during the main rotation of the wafer W.

The precision movement amounts may refer to the movement amounts of the bevel lens 423 and the bevel detector 430 at the respective wafer rotation angles. Because the wafer W rotates once with the center of the chuck 500 as the rotation axis, the wafer rotation angles may include angle values from 0 degrees to 360 degrees. For example, the precision movement amounts may include data indicating that the bevel lens 423 and the bevel detector 430 are moved 30 μm in the second horizontal direction (e.g., the +Y direction) when a wafer rotation angle is 10 degrees and data indicating that the bevel lens 423 and the bevel detector 430 are moved 100 μm in the second horizontal direction (e.g., the +Y direction) when a wafer rotation angle is 30 degrees. This is just an example of the data of precision movement amounts, and the data of precision movement amounts may be implemented in various forms.

According to an implementation, because the method of compensating for a wafer alignment error includes the first to third operations, the wafer alignment error may be compensated for in real time. In detail, the controller 600 may identify the expected rotation trajectory of the wafer W and identify a plurality of precision movement amounts in a short time based on the expected rotation trajectory, by performing the first to third operations. This is described in detail below.

FIGS. 15 and 16 are respectively an image and a graph illustrating an eccentricity identification method of a wafer inspection apparatus, according to an implementation.

FIG. 15 may be a first edge image acquired from an alignment optical system. As shown in FIG. 15, the first edge image may correspond to an area scan image. Alternatively, the first edge image may correspond to a line scan image.

Referring to FIG. 15, the controller 600 may acquire the first edge image from the alignment detector and identify a boundary point 702 between an edge region ER and a dark region DR of the wafer W based on the first edge image. The dark region DR may refer to a region in which the wafer W is not arranged and no object is detected.

According to an implementation, the controller 600 may identify a variance in pixel value (e.g., gray value) of each of the pixels of the first edge image from adjacent pixels and may identify a boundary line 701 based on the identified variances. The controller 600 may identify, as the boundary point 702, a point that most protrudes in the first horizontal direction (e.g., the +Y direction) among a plurality of points of the boundary line 701.

For example, when the first edge image is composed of 100*100 pixels, the controller 600 may identify a variance in pixel value of each of the 10000 pixels from adjacent pixels and may identify the boundary line 701 by identifying points corresponding to pixels having large variances. The controller 600 may identify a point, which has the largest Y value on the boundary line 701, as the boundary point 702.

According to some implementations, the controller 600 may identify the boundary point 702 based on pixel values of central pixels in the first horizontal direction among the pixels of the first edge image. The central pixels in the first horizontal direction may be defined on the basis of a center line in the first horizontal direction, which divides the first edge image into two equal parts and is parallel with the first horizontal direction. In detail, the central pixels in the first horizontal may be arranged on the central line in the first horizontal direction.

The controller 600 may identify a variance in pixel value (e.g. a gray value) of each of the central pixels in the first horizontal from adjacent pixels and identify, as the boundary point 702, a point corresponding to a pixel having the largest variance. This is described with reference to FIG. 16 below.

FIG. 16 is a graph showing gray values of the central pixels in the first horizontal. In the graph of FIG. 16, the x-axis indicates the position of each pixel, and the y-axis indicates the gray value of each pixel.

Referring to FIG. 16, it may be seen that a point at which a variance in pixel values of adjacent pixels is the largest is identified at a pixel located at around the 600th to 610th place from the top of the first edge image in the first horizontal direction. For convenience of description, a point at which a variance in pixel values of adjacent pixels is the largest is referred to as a peak point 703.

The controller 600 may identify the position of the peak point 703, at which a variance in pixel values of adjacent pixels is the largest, as the position of the boundary point 702. Subsequently, the controller 600 may identify a distance from a reference point, i.e., the boundary point 702, in the first horizontal direction. Here, the reference point may refer to the boundary point of the wafer W, which is identified from the first edge image when the center of the wafer W coincides with the center of the chuck 500.

For example, the controller 600 may identify that the peak point 703 is located 600 pixels downward from the topmost pixel of the first edge image and that the position of the boundary point 702 is located 600 pixels downward from the topmost pixel of the first edge image. In this case, when the reference point is located 700 pixels downward from the top of the first edge image, the controller 600 may identify that the boundary point 702 is 100 pixels apart from the reference point in the first horizontal direction (e.g., the +Y direction).

The controller 600 may convert the unit of a distance of the boundary point 702 from the reference point in the first horizontal direction from “pixel” into “μm” based on resolution information of the first edge image and may identify the distance in μm as an “eccentricity in the first horizontal direction”. For example, when the distance in the first horizontal direction is 100 pixels, the controller 600 may convert 100 pixels into 50 μm. However, the random values are just exemplified in the example described above for convenience of description, and a conversion ratio may be determined based on the resolution of the first edge image.

It has been described that the controller 600 acquires an eccentricity in the first horizontal direction based on the first edge image acquired from the alignment optical system 100. However, the controller 600 may acquire an eccentricity in the second horizontal direction based on a second edge image acquired from the upper optical system 200 by using a method that is the same as or similar to the method described above in detail with reference to FIGS. 15 and 16. In this case, the upper optical system 200 may be located at a position rotated around the center of the chuck 500 by 90 degrees from the alignment optical system 100.

The second edge image may be acquired from the lower optical system 300 located at a position rotated around the center of the chuck 500 by 90 degrees from the alignment optical system 100. In this case, the controller 600 may also acquire the eccentricity in the second horizontal direction based on the second edge image by using the same method.

FIG. 17 is a diagram illustrating a method of identifying, by a wafer inspection apparatus, an expected rotation trajectory, according to an implementation.

Referring to FIG. 17, a wafer center CW may be eccentric from a chuck center CC by an eccentricity Δy in the first horizontal direction and an eccentricity Δx in the second horizontal direction.

The horizontal direction in which the linear stage 440 moves the bevel lens 423 and the bevel detector 430 may be parallel to the traveling direction of the bevel light BL from the second bevel mirror 422 toward the bevel lens 423. For example, the horizontal direction in which the linear stage 440 moves the bevel lens 423 and the bevel detector 430 may be a first horizontal direction (Y direction). In another example, the horizontal direction in which the linear stage 440 moves the bevel lens 423 and the bevel detector 430 may be a second horizontal direction (X direction). Additionally, the horizontal direction in which the linear stage 440 moves the bevel lens 423 and the bevel detector 430 may be a direction that is not parallel to the first horizontal direction (Y direction) or the second horizontal direction (X direction).

The controller 600 may identify the expected rotation trajectory of the wafer W based on the eccentricity Δy in the first horizontal direction and the eccentricity Δx in the second horizontal direction. In detail, the wafer W may be fixed to the top surface of the chuck 500 by an electrostatic force and may rotate at the same angular velocity as the chuck 500 based on the rotation of the chuck 500. Accordingly, when there is a wafer alignment error, the wafer center CW may rotate around the chuck center CC in a circular trajectory according to the rotation of the rotating stage 510. The circular trajectory drawn by the wafer center CW may be a circle having the chuck center CC as the center thereof and an eccentricity (e.g., {square root over ((Δx)²+(Δy)²))} of the wafer W as the radius thereof.

The controller 600 may identify the expected rotation trajectory of the wafer W based on the size of the wafer W and the rotation trajectory of the wafer center CW. The controller 600 may quickly acquire an edge scan image based on the expected rotation trajectory. This is described in detail with reference to FIGS. 18 and 19 below.

FIG. 18 is a flowchart of a method of identifying, by a wafer inspection apparatus, a boundary line of a wafer, according to an implementation.

Referring to FIG. 18, in the fourth operation, an alignment image or upper image corresponding to each of the wafer rotation angles may be acquired during the pre-rotation of the wafer W in operation S 1410.

According to an implementation, the controller 600 may control the rotating stage 510 to pre-rotate the wafer W. During the pre-rotation of the wafer W, the controller 600 may acquire an alignment image corresponding to each of the wafer rotation angles from an alignment detector or an upper image corresponding to each of the wafer rotation angles from the upper detector 230. Here, in operation S1410 in which the alignment image or the upper image is acquired, the alignment image or the upper image acquired by the controller 500 may correspond to a line scan image.

As described above, the wafer rotation angles may include 0 degrees to 360 degrees. Accordingly, the controller 600 may sequentially acquire alignment images from an alignment image corresponding to a wafer rotation angle of 0 degrees to an alignment image corresponding to a wafer rotation angle of 360 degrees. The controller 600 may sequentially acquire upper images from an upper image corresponding to a wafer rotation angle of 0 degrees to an upper image corresponding to a wafer rotation angle of 360 degrees.

Subsequently, a region corresponding to the boundary of the wafer W in the entire region of the alignment image or the upper image may be identified based on the expected rotation trajectory of the wafer W in operation S1420. Based on a pixel value in the identified region, a boundary line may be identified in operation S1430.

According to an implementation, the controller 600 may identify a region corresponding to wafer W in the entire region of the alignment image or the upper image, based on the expected rotation trajectory of the wafer W. For convenience of description, a method of identifying a region corresponding to the boundary of the wafer W is described only on the basis of the alignment image.

To identify the boundary line of the wafer W in the alignment image, the controller 600 may use pixel values in the entire region of the alignment image. In this case, pixel value data to be processed by the controller 600 may be huge, and therefore, a long time may be required to identify the boundary line of the wafer W.

Accordingly, in operation S1420 in which a region corresponding to the boundary of the wafer W is identified in a method of compensating for a wafer alignment error, according to an implementation, the controller 600 may identify only a region corresponding to the boundary of the wafer W based on the expected rotation trajectory and identify the boundary line of the wafer W by using pixel values only in the identified region. Consequently, only a short time may be require to identify the boundary line of a wafer, and a wafer inspection apparatus according to an implementation may compensate for a wafer alignment error in real time.

This is described in detail with reference to FIG. 19 below. A method of identifying a region corresponding to the boundary of the wafer W in the entire region of an upper image may be the same as a method of identifying a region corresponding to the boundary of the wafer W in the entire region of an alignment image, and thus, descriptions thereof are omitted.

Although not shown in FIG. 18, the controller 600 may acquire a lower image corresponding to each of the wafer rotation angles from the lower detector 330. The controller 600 may identify a region corresponding to the boundary of a wafer in the entire region of the lower image, based on the expected rotation trajectory of the wafer W and may identify a boundary line of the lower image based on pixel values in the identified region.

FIG. 19 is an image illustrating a method of acquiring, by a wafer inspection apparatus, an edge scan image, according to an implementation.

Referring to FIG. 19, the edge scan image may include a boundary line BL and a reference line RL. Here, the boundary line BL may include information about a point at which the boundary of the wafer W is located at each of the wafer rotation angles. The reference line RL may include information about a point at which the boundary of the wafer W is located at each of the wafer rotation angles when the wafer center CW coincides with the chuck center CC.

The edge scan image may be an alignment image acquired from an alignment detector, an upper image acquired from the upper detector 230, or a lower image acquired from the lower detector 330.

For example, when the controller 600 identifies the boundary line BL of the wafer W based on an upper image corresponding to each of the wafer rotation angles, the upper image may be the edge scan image. When the controller 600 identifies the boundary line BL of the wafer W based on a lower image corresponding to each of the wafer rotation angles, the lower image may be the edge scan image. When the controller 600 identifies the boundary line BL of the wafer W based on an alignment image corresponding to each of the wafer rotation angles, the alignment image may be the edge scan image.

According to an implementation, the controller 600 may identify a region corresponding to the boundary of the wafer W based on the expected rotation trajectory. The controller 600 may identify a candidate region, in which the boundary of the wafer W may be located, at each of the wafer rotation angles based on the expected rotation trajectory of the wafer W.

For example, referring back to FIGS. 15 and 16, when a wafer rotation angle is 10 degrees based on the expected rotation trajectory, the controller 600 may identify, as the “region corresponding to the boundary”, a region located about 500 pixels to about 550 pixels downward from the top of the alignment image, may detect the peak point 703 only in the candidate region, and may identify the peak point 703 as the boundary point 702. When a wafer rotation angle is 20 degrees based on the expected rotation trajectory, the controller 600 may identify, as the “region corresponding to the boundary”, a region located about 550 pixels to about 600 pixels downward from the top of the alignment image. When a wafer rotation angle is 30 degrees based on the expected rotation trajectory, the controller 600 may identify, as the “region corresponding to the boundary”, a region located about 530 pixels to about 580 pixels downward from the top of the alignment image.

The description above is just an example of a method of identifying, by the controller 600, a “region corresponding to the boundary”. A method of identifying a region corresponding to a boundary is not limited to the description above.

The controller 600 may identify the region corresponding to the boundary and identify the boundary line BL based on pixel values in the region. A method of identifying a boundary point based on a pixel value has been described with reference to FIGS. 15 and 16 above, and thus, detailed descriptions thereof are omitted.

The controller 600 may identify a wafer eccentricity Δd corresponding to each of the wafer rotation angles. For example, the controller 600 may identify that the wafer eccentricity is d1 when the wafer rotation angle is 10 degrees, the wafer eccentricity is d2 when the wafer rotation angle is 20 degrees, and the wafer eccentricity is d5 when the wafer rotation angle is 50 degrees. Here, the wafer eccentricity Δd may indicate the distance between the boundary line BL and the reference line RL.

The controller 600 may identify precision movement amounts respectively corresponding to the wafer rotation angles, based on respective wafer eccentricities Δd. For example, because a wafer eccentricity is 20 μm when a wafer rotation angle is 50 degrees, the controller 600 may identify 20 μm as a precision movement amount corresponding to the wafer rotation angle of 50 degrees. Although it has been described that a wafer eccentricity has the same value as a precision movement amount, this is just for convenience of description. The wafer eccentricity and the precision movement amount may be different from or the same as each other according to the arrangement of the bevel detector 430, the bevel lens 423, the bevel light source 410, etc.

Based on the method described above, the controller 600 may identify a plurality of precision movement amounts and control the linear stage 440 in real time during the main rotation of the wafer W to move the bevel lens 423 and the bevel detector 430. Accordingly, the wafer inspection apparatus 1000 according to an implementation may compensate for a wafer alignment error in real time.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A wafer inspection apparatus comprising:
a chuck configured to hold a wafer on a top surface of the chuck;
an upper optical system above the chuck and configured to acquire an upper image of an upper edge of the wafer; and
a bevel optical system located at a position offset by 90 degrees in a first circumferential direction relative to the upper optical system with respect to a central axis of the chuck, the bevel optical system being configured to acquire a bevel image of the wafer,
wherein the upper optical system includes:
an upper coaxial light source above the wafer and configured to output a first upper light radiated to the upper edge of the wafer in a vertical direction;
an upper non-coaxial light source being laterally offset from the wafer and configured to output a second upper light radiated to the upper edge of the wafer at an inclined angle with respect to the vertical direction; and
an upper detector configured to detect the first upper light reflected from the upper edge of the wafer and the second upper light reflected from the upper edge of the wafer, and
wherein the bevel optical system includes:
a bevel light source arranged apart from a bevel of the wafer, the bevel light source including a plurality of bevel light-emitting diodes (LEDs) surrounding an outer surface of the bevel of the wafer, the bevel light source being configured to output a bevel light radiated to a bevel apex of the wafer; and
a bevel detector configured to detect the bevel light reflected from the bevel apex of the wafer.

2. The wafer inspection apparatus of claim 1, wherein the bevel light source includes a bevel structure, and
wherein the bevel structure includes a recess, the recess is spaced apart from the bevel of the wafer and surrounds the outer surface of the bevel of the wafer, and the plurality of bevel LEDs are arranged in a U-shape on a surface of the recess.

3. The wafer inspection apparatus of claim 2, wherein the bevel light source includes a bevel diffuser,
wherein the bevel diffuser is arranged in an optical path of the plurality of bevel LEDs and configured to diffuse the bevel light that is output from the plurality of bevel LEDs, and
wherein the bevel optical system is configured to radiate the diffused bevel light to the bevel apex of the wafer.

4. The wafer inspection apparatus of claim 1, wherein the inclined angle is 30 degrees to 130 degrees.

5. The wafer inspection apparatus of claim 1, wherein the inclined angle is 110 degrees.

6. The wafer inspection apparatus of claim 1, wherein the upper non-coaxial light source includes a reflective upper structure,
wherein the reflective upper structure includes at least one upper LED and a diffuse reflection coating film, the at least one upper LED is configured to output the second upper light, and the diffuse reflection coating film is on an inner wall of the reflective upper structure and configured to diffusely reflect the second upper light that is output from the at least one upper LED, and
wherein the upper optical system is configured to radiate the diffusely reflected second upper light to the upper edge of the wafer.

7. The wafer inspection apparatus of claim 1, wherein the upper non-coaxial light source includes a transmissive upper structure,
wherein the transmissive upper structure includes at least one upper LED and an upper diffuser, the at least one upper LED is configured to output the second upper light, and the upper diffuser is arranged in an optical path of the at least one upper LED and configured to scatter the second upper light that is output from the at least one upper LED, and
wherein the upper optical system is configured to radiate the scattered second upper light to the upper edge of the wafer.

8. The wafer inspection apparatus of claim 1, comprising
an alignment optical system located at a position offset by 90 degrees in a second circumferential direction relative to the upper optical system with respective to the central axis of the chuck, the second circumferential direction being opposite to the first circumferential direction; and
a rotating stage configured to rotate the wafer around the central axis of the chuck by rotating the chuck,
wherein the alignment optical system includes an alignment detector configured to acquire an alignment image indicating an alignment between the wafer and the chuck, and
wherein the bevel optical system includes:
a bevel mirror configured to transmit the bevel light reflected from the bevel apex of the wafer to the bevel detector;
a bevel lens configured to collimate the bevel light transmitted from the bevel mirror; and
a linear stage configured to adjust a horizontal distance between the bevel mirror and the bevel lens by moving the bevel lens and the bevel detector in a horizontal direction.

9. The wafer inspection apparatus of claim 8, comprising:
a controller configured to control the rotating stage and the linear stage,
wherein the controller is configured to
acquire a first edge image of the wafer from the alignment detector and a second edge image of the wafer from the upper detector,
identify an eccentricity in a first horizontal direction based on the first edge image and an eccentricity in a second horizontal direction based on the second edge image,
identify an expected rotation trajectory of the wafer based on the eccentricity in the first horizontal direction and the eccentricity in the second horizontal direction,
control the rotating stage to perform a first rotation of the wafer and acquire an edge scan image based on the expected rotation trajectory during the first rotation of the wafer,
identify, based on the edge scan image, a plurality of precision movement amounts respectively corresponding to a plurality of wafer rotation angles,
control the wafer to perform a main rotation by controlling the rotating stage, and
move, by controlling the linear stage, the bevel lens and the bevel detector by each of the plurality of precision movement amounts in the horizontal direction during the main rotation of the wafer,
wherein the first horizontal direction is a direction from a center of the chuck to the position of the alignment optical system, and the second horizontal direction is perpendicular to the first horizontal direction.

10. The wafer inspection apparatus of claim 9, wherein
the edge scan image includes a boundary line and a reference line,
the boundary line indicates a location of a boundary of the wafer at each of the plurality of wafer rotation angles, and
the reference line indicates a reference location of the boundary of the wafer at each of the plurality of wafer rotation angles when the center of the wafer coincides with the center of the chuck.

11. The wafer inspection apparatus of claim 10, wherein the controller is configured to
acquire the alignment image corresponding to each of the plurality of wafer rotation angles from the alignment detector during the first rotation of the wafer,
identify, based on the expected rotation trajectory of the wafer, a region corresponding to the boundary of the wafer in an entire region of the alignment image, and
identify the boundary line based on pixel values of pixels in the identified region.

12. The wafer inspection apparatus of claim 10, wherein the controller is configured to
acquire the upper image corresponding to each of the plurality of wafer rotation angles from the upper detector during the first rotation of the wafer,
identify, based on the expected rotation trajectory of the wafer, a region corresponding to the boundary of the wafer in an entire region of the upper image, and
identify the boundary line based on pixel values of pixels in the identified region.

13. A wafer inspection apparatus comprising:
a chuck configured to hold a wafer on a top surface of the chuck;
a lower optical system below the chuck and configured to acquire a lower image of a lower edge of the wafer; and
a bevel optical system located at a position offset by 90 degrees in a first circumferential direction relative to the lower optical system with respect to a central axis of the chuck and configured to acquire a bevel image of the wafer,
wherein the lower optical system includes:
a lower coaxial light source below the wafer and configured to output a first lower light radiated to the lower edge of the wafer in a vertical direction;
a lower non-coaxial light source being laterally offset from the wafer and configured to output a second lower light radiated to the lower edge of the wafer at an inclined angle with respect to the vertical direction; and
a lower detector configured to detect the first lower light reflected from the lower edge of the wafer and the second lower light reflected from the lower edge of the wafer, and
wherein the bevel optical system includes:
a bevel light source arranged apart from a bevel of the wafer, the bevel light source including a plurality of bevel light-emitting diodes (LEDs) surrounding an outer surface of the bevel of the wafer, the bevel light source being configured to output a bevel light radiated to a bevel apex of the wafer; and
a bevel detector configured to detect the bevel light reflected from the bevel apex of the wafer.

14. The wafer inspection apparatus of claim 13, wherein the bevel light source includes a bevel structure,
wherein the bevel structure includes a recess, the recess is spaced apart from the bevel of the wafer and surrounds the outer surface of the bevel of the wafer, and the plurality of bevel LEDs are arranged in a U-shape on a surface of the recess.

15. The wafer inspection apparatus of claim 13, wherein the inclined angle is 30 degrees to 130 degrees.

16. The wafer inspection apparatus of claim 13, comprising:
an alignment optical system located at a position offset by 90 degrees in a second circumferential direction relative to the lower optical system with respect to the central axis of the chuck, the second circumferential direction being opposite to the first circumferential direction; and
a rotating stage configured to rotate the wafer around the central axis of the chuck by rotating the chuck,
wherein the alignment optical system includes an alignment detector configured to acquire an alignment image indicating an alignment between the wafer and the chuck, and
wherein the bevel optical system includes:
a bevel mirror configured to transmit the bevel light reflected from the bevel apex of the wafer to the bevel detector;
a bevel lens configured to collimate the bevel light transmitted from the bevel mirror; and
a linear stage configured to adjust a horizontal distance between the bevel mirror and the bevel lens by moving the bevel lens and the bevel detector in a horizontal direction.

17. The wafer inspection apparatus of claim 16, comprising
a controller configured to control the rotating stage and the linear stage,
wherein the controller is configured to
acquire a first edge image of the wafer from the alignment detector and a second edge image of the wafer from the lower detector,
identify an eccentricity in a first horizontal direction based on the first edge image and an eccentricity in a second horizontal direction based on the second edge image,
identify an expected rotation trajectory of the wafer based on the eccentricity in the first horizontal direction and the eccentricity in the second horizontal direction,
control the rotating stage to perform a first rotation of the wafer,
acquire an edge scan image based on the expected rotation trajectory during the first rotation of the wafer,
identify, based on the edge scan image, a plurality of precision movement amounts respectively corresponding to a plurality of wafer rotation angles,
control the wafer to perform a main rotation by controlling the rotating stage, and
move, by controlling the linear stage, the bevel lens and the bevel detector by each of the plurality of precision movement amounts in the horizontal direction during the main rotation of the wafer,
wherein the first horizontal direction is a direction from a center of the chuck to the position of the alignment optical system, and the second horizontal direction is perpendicular to the first horizontal direction.

18. The wafer inspection apparatus of claim 17, wherein
the edge scan image includes a boundary line and a reference line,
the boundary line indicates a location of a boundary of the wafer at each of the plurality of wafer rotation angles, and
the reference line indicates a reference location of the boundary of the wafer at each of the plurality of wafer rotation angles when the center of the wafer coincides with the center of the chuck.

19. A wafer inspection apparatus comprising:
a chuck configured to hold a wafer on a top surface of the chuck;
an upper optical system above the chuck and configured to acquire an upper image of an upper edge of the wafer;
a lower optical system arranged at a position symmetrical with a position the upper optical system with respect to a central axis of the chuck and configured to acquire a lower image of a lower edge of the wafer;
a bevel optical system located at a position offset by 90 degrees in a circumferential direction relative to the upper optical system with respect to the central axis of the chuck and configured to acquire a bevel image of the wafer; and
an alignment optical system arranged at a position symmetrical with the position of the bevel optical system with respect to the central axis of the chuck and configured to acquire an alignment image indicating an alignment between the wafer and the chuck,
wherein the upper optical system includes:
an upper coaxial light source above the wafer and configured to output a first upper light radiated to the upper edge of the wafer in a vertical direction;
an upper non-coaxial light source being laterally offset from the wafer and configured to output a second upper light radiated to the upper edge of the wafer at a first angle inclined with respect to the vertical direction; and
an upper detector configured to detect the first upper light reflected from the upper edge of the wafer and the second upper light reflected from the upper edge of the wafer,
wherein the lower optical system includes:
a lower coaxial light source below the wafer and configured to output a first lower light radiated to the lower edge of the wafer in the vertical direction;
a lower non-coaxial light source being laterally offset from the wafer and configured to output a second lower light radiated to the lower edge of the wafer at a second angle inclined with respect to the vertical direction; and
a lower detector configured to detect the first lower light reflected from the lower edge of the wafer and the second lower light reflected from the lower edge of the wafer, and
wherein the bevel optical system includes:
a bevel light source arranged apart from a bevel of the wafer, the bevel light source including a plurality of bevel light-emitting diodes (LEDs) surrounding an outer surface of the bevel of the wafer, the bevel light source being configured to output a bevel light radiated to a bevel apex of the wafer; and
a bevel detector configured to detect the bevel light reflected from the bevel apex of the wafer,
wherein each of the first angle and the second angle is 30 degrees to 130 degrees.

20. The wafer inspection apparatus of claim 19, comprising
a rotating stage configured to rotate the wafer around the central axis of the chuck by rotating the chuck,
wherein the alignment optical system includes an alignment detector configured to acquire the alignment image, and
wherein the bevel optical system includes:
a bevel mirror configured to transmit the bevel light reflected from the bevel apex of the wafer to the bevel detector;
a bevel lens configured to collimate the bevel light transmitted from the bevel mirror; and
a linear stage configured to adjust a horizontal distance between the bevel mirror and the bevel lens by moving the bevel lens and the bevel detector in a horizontal direction.
